(19) United States
(12) Patent Application Publication
(10) Pub. No.: US 2026/0246564 A1
(43) Pub. Date: Aug. 20, 2026

(54) TECHNIQUES FOR ITERATIVE DECODING USING TURBO SPINAL CODES

(71) Applicant: QUALCOMM INCORPORATED, San Diego, CA (US)

(72) Inventors: Jian LI, Shanghai (CN); Changlong XU, Beijing (CN); Liangming WU, Beijing (CN); Kangqi LIU, San Diego, CA (US); Wei LIU, Beijing (CN); Hao XU, Beijing (CN); Jing JIANG, San Diego, CA (US); Danlu Zhang, San Diego, CA (US)

(21) Appl. No.: 18/992,901

(22) PCT Filed: Aug. 24, 2022
(86) PCT No.: PCT/CN2022/114419

§ 371 Date: Jan. 9, 2025

(51) Int. Cl. H04L 1/00

(52) U.S. Cl. CPC H04L 1/005; H04L 1/0036

(57) ABSTRACT

Methods, systems, and devices for wireless communications are described. In some wireless communications systems, a wireless device may receive a message including a set of bits partitioned into a set of submessages. In some aspects, the wireless device may generate a first set of submessage candidates, interleave the first set of submessage candidates to generate a set of interleaved submessage candidates, generate a second set of submessage candidates using the set of interleaved submessage candidates, and attempt to decode the message based on the first and second pluralities of submessage candidates. In other aspects, the wireless device may generate a first set of soft information, interleave the first set of soft information to generate a set of interleaved soft information, generate a second set of soft information using the set of interleaved soft information, and attempt to decode the message based on the first and second sets of soft information.

### CROSS REFERENCE

The present application is a 371 national stage filing of International PCT Application No. PCT/CN2022/114419 by LI et al. entitled “TECHNIQUES FOR ITERATIVE DECODING USING TURBO SPINAL CODES,” filed Aug. 24, 2022, which is assigned to the assignee hereof, and which is expressly incorporated by reference in its entirety herein.

### FIELD OF TECHNOLOGY

The following relates to wireless communications, including techniques for iterative decoding using turbo spinal codes.

### BACKGROUND

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM).

A wireless multiple-access communications system may include one or more base stations, each supporting wireless communication for communication devices, which may be known as user equipment (UE). In some examples, a transmitting device or a receiving device may utilize a turbo spinal code to decode a message that includes a set of bits.

### SUMMARY

The described techniques relate to improved methods, systems, devices, and apparatuses that support techniques for iterative decoding using turbo spinal codes. For example, the described techniques provide for a receiving device (e.g., a user equipment (UE), a network entity) to support an iterative decoding algorithm for a turbo spinal code, where the iterative decoding algorithm may improve the decoding performance of the receiving device. The receiving device may receive a message (e.g., an encoded message) including a set of bits partitioned into a set of submessages. In some aspects, the receiving device may perform decoding of the message using an iterative list decoding process. In such aspects, the receiving device may perform a first list search operation associated with a first spinal code tree of an iterative list decoding process to generate a first set of submessage candidates. Additionally, the receiving device may interleave the first set of submessage candidates to generate a set of interleaved submessage candidates, and the receiving device may perform a second list search operation associated with a second spinal code tree of the iterative list decoding process using the set of interleaved submessage candidates to generate a second set of submessage candidates. Based on the first set of submessage candidates and the second set of submessage candidates, the receiving device may attempt to decode the message. In some cases, the receiving device may continue the iterative list decoding process by deinterleaving the second set of submessage candidates to generate an input for the first list search operation associated with the first spinal code in a next iteration of the iterative list decoding process.

In some other aspects, the receiving device may perform decoding using an iterative soft decoding process. For example, the receiving device may perform a first soft decoding operation associated with a first spinal code to generate a first set of soft information. Additionally, the receiving device may interleave the first set of soft information using an interleaver to generate an interleaved set of soft information, and the receiving device may perform a second soft decoding operation associated with a second spinal code on the interleaved set of soft information to generate a second set of soft information. Based on the first set of soft information and the second set of soft information, the receiving device may attempt to decode the message. In some cases, the receiving device may continue the iterative soft decoding process by deinterleaving the second set of soft information to generate an input for the first soft decoding operation associated with the first spinal code in a next iteration of the iterative soft process.

A method for wireless communication at a wireless device is described. The method may include receiving a message including a set of multiple bits partitioned into a set of multiple submessages, performing a first list search operation associated with a first spinal code tree of an iterative list decoding process to generate a first set of multiple submessage candidates, interleaving the first set of multiple submessage candidates to generate a set of interleaved submessage candidates, performing a second list search operation associated with a second spinal code tree of the iterative list decoding process using the set of interleaved submessage candidates to generate a second set of multiple submessage candidates, and attempting to decode the message based on the first set of multiple submessage candidates and the second set of multiple submessage candidates.

An apparatus for wireless communication at a wireless device is described. The apparatus may include a processor, memory coupled with the processor, and instructions stored in the memory. The instructions may be executable by the processor to cause the apparatus to receive a message including a set of multiple bits partitioned into a set of multiple submessages, perform a first list search operation associated with a first spinal code tree of an iterative list decoding process to generate a first set of multiple submessage candidates, interleave the first set of multiple submessage candidates to generate a set of interleaved submessage candidates, perform a second list search operation associated with a second spinal code tree of the iterative list decoding process using the set of interleaved submessage candidates to generate a second set of multiple submessage candidates, and attempt to decode the message based on the first set of multiple submessage candidates and the second set of multiple submessage candidates.

Another apparatus for wireless communication at a wireless device is described. The apparatus may include means for receiving a message including a set of multiple bits partitioned into a set of multiple submessages, means for performing a first list search operation associated with a first spinal code tree of an iterative list decoding process to generate a first set of multiple submessage candidates, means for interleaving the first set of multiple submessage candidates to generate a set of interleaved submessage candidates, means for performing a second list search operation associated with a second spinal code tree of the iterative list decoding process using the set of interleaved submessage candidates to generate a second set of multiple submessage candidates, and means for attempting to decode the message based on the first set of multiple submessage candidates and the second set of multiple submessage candidates.

A non-transitory computer-readable medium storing code for wireless communication at a wireless device is described. The code may include instructions executable by a processor to receive a message including a set of multiple bits partitioned into a set of multiple submessages, perform a first list search operation associated with a first spinal code tree of an iterative list decoding process to generate a first set of multiple submessage candidates, interleave the first set of multiple submessage candidates to generate a set of interleaved submessage candidates, perform a second list search operation associated with a second spinal code tree of the iterative list decoding process using the set of interleaved submessage candidates to generate a second set of multiple submessage candidates, and attempt to decode the message based on the first set of multiple submessage candidates and the second set of multiple submessage candidates.

Some examples of the method, apparatuses, and non-transitory computer-readable medium described herein may further include operations, features, means, or instructions for deinterleaving the second set of multiple submessage candidates to generate an input for the first list search operation associated with the first spinal code tree in a next iteration of the iterative list decoding process.

In some examples of the method, apparatuses, and non-transitory computer-readable medium described herein, the next iteration may be based on a failure of a current iteration to meet a maximum iteration threshold of the iterative list decoding process.

In some examples of the method, apparatuses, and non-transitory computer-readable medium described herein, the interleaving, deinterleaving, or both may be based on a row-in column-out rectangular interleaver, a triangular interleaver, a pseudo-random interleaver, or a two-way spinal interleaver.

Some examples of the method, apparatuses, and non-transitory computer-readable medium described herein may further include operations, features, means, or instructions for determining a quantity of submessage candidates remaining after the attempting to decode the message and terminating the iterative list decoding process based on determining that the quantity of submessage candidates remaining after the attempting to decode the message may be equal to one.

In some examples of the method, apparatuses, and non-transitory computer-readable medium described herein, the attempting to decode the message may include operations, features, means, or instructions for performing a cyclic redundancy check based on a message candidate corresponding to a first submessage candidate of the first set of multiple submessage candidates and a second submessage candidate of the second set of multiple submessage candidates and terminating the iterative list decoding process based on a success of the cyclic redundancy check.

Some examples of the method, apparatuses, and non-transitory computer-readable medium described herein may further include operations, features, means, or instructions for identifying that at least two submessage candidates of the second set of multiple submessage candidates may be remaining based on performing the second list search operation on the second spinal code tree and performing a next iteration of the iterative list decoding process based on identifying that the at least two submessage candidates of the second set of multiple submessage candidates may be remaining.

Some examples of the method, apparatuses, and non-transitory computer-readable medium described herein may further include operations, features, means, or instructions for determining that one or more submessage candidates fail to satisfy a path metric based on performing the second list search operation on the second spinal code tree and refraining from including the one or more submessage candidates in the second set of multiple submessage candidates based on the determining.

In some examples of the method, apparatuses, and non-transitory computer-readable medium described herein, the first set of multiple submessage candidates, the second set of multiple submessage candidates, or both may be generated based on a threshold quantity of submessage candidates.

A method for wireless communication at a wireless device is described. The method may include receiving a message including of a first set of multiple bits partitioned into a set of multiple submessages, performing a first soft decoding operation associated with a first spinal code of an iterative soft decoding process to generate a first set of soft information, interleaving the first set of soft information using an interleaver to generate a set of interleaved soft information, performing a second soft decoding operation associated with a second spinal code of the iterative soft decoding process using the set of interleaved soft information to generate a second set of soft information, and attempting to decode the message based on the first set of soft information and the second set of soft information.

An apparatus for wireless communication at a wireless device is described. The apparatus may include a processor, memory coupled with the processor, and instructions stored in the memory. The instructions may be executable by the processor to cause the apparatus to receive a message including of a first set of multiple bits partitioned into a set of multiple submessages, perform a first soft decoding operation associated with a first spinal code of an iterative soft decoding process to generate a first set of soft information, interleave the first set of soft information using an interleaver to generate a set of interleaved soft information, perform a second soft decoding operation associated with a second spinal code of the iterative soft decoding process using the set of interleaved soft information to generate a second set of soft information, and attempt to decode the message based on the first set of soft information and the second set of soft information.

Another apparatus for wireless communication at a wireless device is described. The apparatus may include means for receiving a message including of a first set of multiple bits partitioned into a set of multiple submessages, means for performing a first soft decoding operation associated with a first spinal code of an iterative soft decoding process to generate a first set of soft information, means for interleaving the first set of soft information using an interleaver to generate a set of interleaved soft information, means for performing a second soft decoding operation associated with a second spinal code of the iterative soft decoding process using the set of interleaved soft information to generate a second set of soft information, and means for attempting to decode the message based on the first set of soft information and the second set of soft information.

A non-transitory computer-readable medium storing code for wireless communication at a wireless device is described. The code may include instructions executable by a processor to receive a message including of a first set of multiple bits partitioned into a set of multiple submessages, perform a first soft decoding operation associated with a first spinal code of an iterative soft decoding process to generate a first set of soft information, interleave the first set of soft information using an interleaver to generate a set of interleaved soft information, perform a second soft decoding operation associated with a second spinal code of the iterative soft decoding process using the set of interleaved soft information to generate a second set of soft information, and attempt to decode the message based on the first set of soft information and the second set of soft information.

Some examples of the method, apparatuses, and non-transitory computer-readable medium described herein may further include operations, features, means, or instructions for deinterleaving the second set of soft information to generate an input for the first soft decoding operation associated with the first spinal code in a next iteration of the iterative soft decoding process.

In some examples of the method, apparatuses, and non-transitory computer-readable medium described herein, the next iteration may be based on a failure of a current iteration to meet a maximum iteration threshold of the iterative soft decoding process.

In some examples of the method, apparatuses, and non-transitory computer-readable medium described herein, the interleaving, deinterleaving, or both, may be based on a row-in column-out rectangular interleaver, a triangular interleaver, a pseudo-random interleaver, or a two-way spinal interleaver.

Some examples of the method, apparatuses, and non-transitory computer-readable medium described herein may further include operations, features, means, or instructions for determining a first log likelihood ratio based on the first set of soft information, determining a second log likelihood ratio based on the second set of soft information, and terminating the iterative soft decoding process based on the first log likelihood ratio, the second log likelihood ratio, or any combination thereof.

Some examples of the method, apparatuses, and non-transitory computer-readable medium described herein may further include operations, features, means, or instructions for performing a cyclic redundancy check based on a message candidate corresponding to the first set of soft information and the second set of soft information and terminating the iterative soft decoding process based on a success of the cyclic redundancy check.

### BRIEF DESCRIPTION OF THE DRAWINGS

FIG. 1 illustrates an example of a wireless communications system that supports techniques for iterative decoding using turbo spinal codes in accordance with one or more aspects of the present disclosure.

FIG. 2 illustrates an example of a wireless communications system that supports techniques for iterative decoding using turbo spinal codes in accordance with one or more aspects of the present disclosure.

FIG. 3 illustrates an example of a spinal coding scheme that supports techniques for iterative decoding using turbo spinal codes in accordance with one or more aspects of the present disclosure.

FIG. 4 illustrates an example of a turbo spinal coding scheme that supports techniques for iterative decoding using turbo spinal codes in accordance with one or more aspects of the present disclosure.

FIG. 5 illustrates an example of a rate matching scheme that supports techniques for iterative decoding using turbo spinal codes in accordance with one or more aspects of the present disclosure.

FIG. 6A illustrates an example of a list decoding block diagram that supports techniques for iterative decoding using turbo spinal codes in accordance with one or more aspects of the present disclosure.

FIG. 6B illustrates an example of a list decoding scheme that supports techniques for iterative decoding using turbo spinal codes in accordance with one or more aspects of the present disclosure.

FIG. 7 illustrates an example of a soft decoding block diagram that supports techniques for iterative decoding using turbo spinal codes in accordance with one or more aspects of the present disclosure.

FIG. 8 illustrates an example of a process flow that supports techniques for iterative decoding using turbo spinal codes in accordance with one or more aspects of the present disclosure.

FIG. 9 illustrates an example of a process flow that supports techniques for iterative decoding using turbo spinal codes in accordance with one or more aspects of the present disclosure.

FIGS. 10 and 11 show block diagrams of devices that support techniques for iterative decoding using turbo spinal codes in accordance with one or more aspects of the present disclosure.

FIG. 12 shows a block diagram of a communications manager that supports techniques for iterative decoding using turbo spinal codes in accordance with one or more aspects of the present disclosure.

FIG. 13 shows a diagram of a system including a UE that supports techniques for iterative decoding using turbo spinal codes in accordance with one or more aspects of the present disclosure.

FIG. 14 shows a diagram of a system including a network entity that supports techniques for iterative decoding using turbo spinal codes in accordance with one or more aspects of the present disclosure.

FIGS. 15 through 18 show flowcharts illustrating methods that support techniques for iterative decoding using turbo spinal codes in accordance with one or more aspects of the present disclosure.

### DETAILED DESCRIPTION

In some wireless communications systems, a transmitting device (e.g., a user equipment (UE), a network entity) may encode a message by using a spinal code. Similarly to encoding with a convolutional code, the transmitting device may use the spinal code to encode the message by performing a logical operation on a current bitstream while also considering bits of a previous bitstream. When encoding the message with the spinal code, the transmitting device may use a hash function h to produce a rateless output including infinite pseudo-random sequences. For example, the transmitting device may partition a message into multiple submessages and begin the encoding process with an initial state. The UE may apply the hash function to the initial state and a first submessage, output a second state for the first submessage, and input the second state into a random number generator (RNG) to produce multiple random outputs. Further, the transmitting device may output a third state for the second submessage based on applying the hash function to the second state and the second submessage, repeating the process until all submessages are encoded.

In some examples, the spinal code may be a “turbo” spinal code including two separate spinal codes for encoding or decoding, where an interleaver is used to generate inputs for a second spinal code based on inputs of a first spinal code. For instance, the transmitting device may use a two-way spinal (e.g., reverse) interleaver to generate submessage inputs for the second spinal code that are the reverse of submessage inputs for the first spinal code, allowing for forward and reverse encoding with the “turbo” spinal code. In some cases, the decoding performance of the receiving device which receives and decodes the message encoded with the turbo spinal code may be improved by reducing signaling overhead.

Techniques described herein support iterative decoding procedures for decoding a message using turbo spinal codes, improving the decoding performance for the receiving device. For example, the UE may use an iterative decoding algorithm for a turbo spinal code that includes a first decoder, a first interleaver, and a second interleaver (e.g., deinterleaver) for decoding a message using the turbo spinal code. In some examples, the receiving device may use iterative list decoders (e.g., bubble decoders) to reduce a quantity of submessage candidates with each iteration of the decoding process until a single submessage candidate remains for a respective submessage or until a maximum iteration threshold for the decoding process is reached. Additionally, or alternatively, the receiving device may use iterative soft decoders to output soft information with each iteration of the decoding process until a maximum threshold for the decoding process is reached, where the soft information may indicate the likelihood for the receiving device to correctly read bits of a submessage. Moreover, the turbo spinal code may include one or more rectangular interleavers (e.g., “row-in column-out” rectangular interleavers), triangular interleavers (e.g., 5G for polar code), pseudo-random interleavers, or reverse interleavers (e.g., two-way spinal interleavers).

By supporting such iterative decoding techniques for turbo spinal codes, the receiving device may further reduce signaling overhead for decoding an encoded message, resulting in improved decoding performance. Additionally, by supporting different types of interleavers for the turbo spinal code, the receiving device may have increased degrees of freedom the decoding procedure, resulting in enhanced flexibility for decoding.

Aspects of the disclosure are initially described in the context of wireless communications systems. Examples of a spinal coding scheme, turbo spinal coding scheme, list decoding block diagram, list decoding scheme, soft decoding block diagram, and process flows supporting techniques for iterative decoding using turbo spinal codes are then described. Aspects of the disclosure are further illustrated by and described with reference to apparatus diagrams, system diagrams, and flowcharts that relate to techniques for iterative decoding using turbo spinal codes.

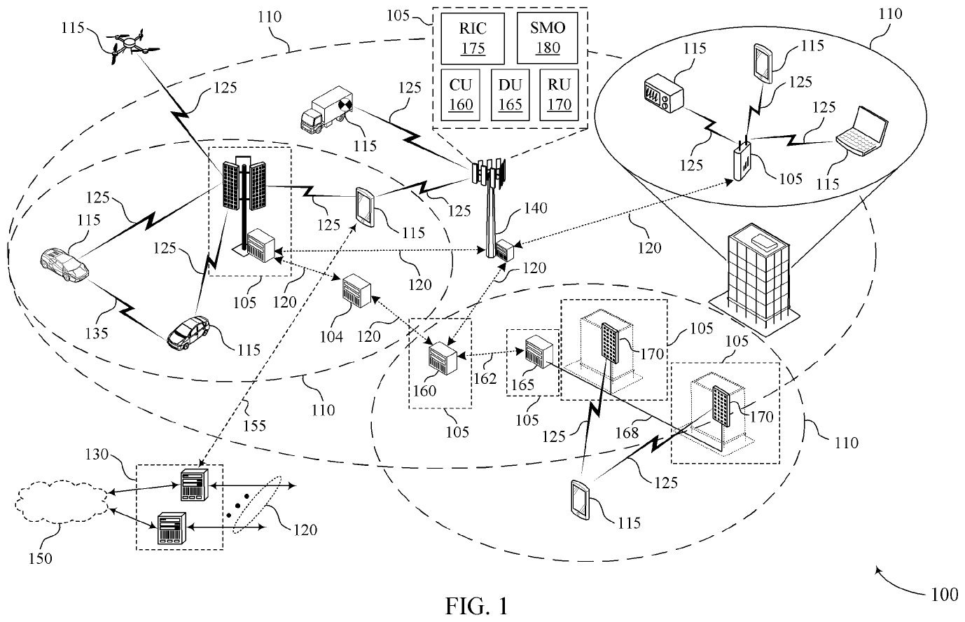

FIG. 1 illustrates an example of a wireless communications system 100 that supports techniques for iterative decoding using turbo spinal codes in accordance with one or more aspects of the present disclosure. The wireless communications system 100 may include one or more network entities 105, one or more UEs 115, and a core network 130. In some examples, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some examples, network entities 105 and UEs 115 may wirelessly communicate via one or more communication links 125 (e.g., a radio frequency (RF) access link). For example, a network entity 105 may support a coverage area 110 (e.g., a geographic coverage area) over which the UEs 115 and the network entity 105 may establish one or more communication links 125. The coverage area 110 may be an example of a geographic area over which a network entity 105 and a UE 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communications with various types of devices, such as other UEs 115 or network entities 105, as shown in FIG. 1.

As described herein, a node of the wireless communications system 100, which may be referred to as a network node, or a wireless node, may be a network entity 105 (e.g., any network entity described herein), a UE 115 (e.g., any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, computing system, or the like may include disclosure of the UE 115, network entity 105, apparatus, device, computing system, or the like being a node. For example, disclosure that a UE 115 is configured to receive information from a network entity 105 also discloses that a first node is configured to receive information from a second node.

In some examples, network entities 105 may communicate with the core network 130, or with one another, or both. For example, network entities 105 may communicate with the core network 130 via one or more backhaul communication links 120 (e.g., in accordance with an S1, N2, N3, or other interface protocol). In some examples, network entities 105 may communicate with one another via a backhaul communication link 120 (e.g., in accordance with an X2, Xn, or other interface protocol) either directly (e.g., directly between network entities 105) or indirectly (e.g., via a core network 130). In some examples, network entities 105 may communicate with one another via a midhaul communication link 162 (e.g., in accordance with a midhaul interface protocol) or a fronthaul communication link 168 (e.g., in accordance with a fronthaul interface protocol), or any combination thereof. The backhaul communication links 120, midhaul communication links 162, or fronthaul communication links 168 may be or include one or more wired links (e.g., an electrical link, an optical fiber link), one or more wireless links (e.g., a radio link, a wireless optical link), among other examples or various combinations thereof. A UE 115 may communicate with the core network 130 via a communication link 155.

One or more of the network entities 105 described herein may include or may be referred to as a base station 140 (e.g., a base transceiver station, a radio base station, an NR base station, an access point, a radio transceiver, a NodeB, an eNodeB (eNB), a next-generation NodeB or a giga-NodeB (either of which may be referred to as a gNB), a 5G NB, a next-generation eNB (ng-eNB), a Home NodeB, a Home eNodeB, or other suitable terminology). In some examples, a network entity 105 (e.g., a base station 140) may be implemented in an aggregated (e.g., monolithic, standalone) base station architecture, which may be configured to utilize a protocol stack that is physically or logically integrated within a single network entity 105 (e.g., a single RAN node, such as a base station 140).

In some examples, a network entity 105 may be implemented in a disaggregated architecture (e.g., a disaggregated base station architecture, a disaggregated RAN architecture), which may be configured to utilize a protocol stack that is physically or logically distributed among two or more network entities 105, such as an integrated access backhaul (IAB) network, an open RAN (O-RAN) (e.g., a network configuration sponsored by the O-RAN Alliance), or a virtualized RAN (vRAN) (e.g., a cloud RAN (C-RAN)). For example, a network entity 105 may include one or more of a central unit (CU) 160, a distributed unit (DU) 165, a radio unit (RU) 170, a RAN Intelligent Controller (RIC) 175 (e.g., a Near-Real Time RIC (Near-RT RIC), a Non-Real Time RIC (Non-RT RIC)), a Service Management and Orchestration (SMO) 180 system, or any combination thereof. An RU 170 may also be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (e.g., separate physical locations). In some examples, one or more network entities 105 of a disaggregated RAN architecture may be implemented as virtual units (e.g., a virtual CU (VCU), a virtual DU (VDU), a virtual RU (VRU)).

The split of functionality between a CU 160, a DU 165, and an RU 170 is flexible and may support different functionalities depending on which functions (e.g., network layer functions, protocol layer functions, baseband functions, RF functions, and any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some examples, the CU 160 may host upper protocol layer (e.g., layer 3 (L3), layer 2 (L2)) functionality and signaling (e.g., Radio Resource Control (RRC), service data adaption protocol (SDAP), Packet Data Convergence Protocol (PDCP)). The CU 160 may be connected to one or more DUs 165 or RUs 170, and the one or more DUs 165 or RUs 170 may host lower protocol layers, such as layer 1 (L1) (e.g., physical (PHY) layer) or L2 (e.g., radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (e.g., via one or more RUs 170). In some cases, a functional split between a CU 160 and a DU 165, or between a DU 165 and an RU 170 may be within a protocol layer (e.g., some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to one or more DUs 165 via a midhaul communication link 162 (e.g., F1, F1-c, F1-u), and a DU 165 may be connected to one or more RUs 170 via a fronthaul communication link 168 (e.g., open fronthaul (FH) interface). In some examples, a midhaul communication link 162 or a fronthaul communication link 168 may be implemented in accordance with an interface (e.g., a channel) between layers of a protocol stack supported by respective network entities 105 that are in communication via such communication links.

In wireless communications systems (e.g., wireless communications system 100), infrastructure and spectral resources for radio access may support wireless backhaul link capabilities to supplement wired backhaul connections, providing an IAB network architecture (e.g., to a core network 130). In some cases, in an IAB network, one or more network entities 105 (e.g., IAB nodes 104) may be partially controlled by each other. One or more IAB nodes 104 may be referred to as a donor entity or an IAB donor. One or more DUs 165 or one or more RUs 170 may be partially controlled by one or more CUs 160 associated with a donor network entity 105 (e.g., a donor base station 140). The one or more donor network entities 105 (e.g., IAB donors) may be in communication with one or more additional network entities 105 (e.g., IAB nodes 104) via supported access and backhaul links (e.g., backhaul communication links 120). IAB nodes 104 may include an IAB mobile termination (LAB-MT) controlled (e.g., scheduled) by DUs 165 of a coupled IAB donor. An IAB-MT may include an independent set of antennas for relay of communications with UEs 115, or may share the same antennas (e.g., of an RU 170) of an IAB node 104 used for access via the DU 165 of the IAB node 104 (e.g., referred to as virtual IAB-MT (vIAB-MT)). In some examples, the IAB nodes 104 may include DUs 165 that support communication links with additional entities (e.g., IAB nodes 104, UEs 115) within the relay chain or configuration of the access network (e.g., downstream). In such cases, one or more components of the disaggregated RAN architecture (e.g., one or more IAB nodes 104 or components of IAB nodes 104) may be configured to operate according to the techniques described herein.

For instance, an access network (AN) or RAN may include communications between access nodes (e.g., an IAB donor), IAB nodes 104, and one or more UEs 115. The IAB donor may facilitate connection between the core network 130 and the AN (e.g., via a wired or wireless connection to the core network 130). That is, an IAB donor may refer to a RAN node with a wired or wireless connection to core network 130. The IAB donor may include a CU 160 and at least one DU 165 (e.g., and RU 170), in which case the CU 160 may communicate with the core network 130 via an interface (e.g., a backhaul link). IAB donor and IAB nodes 104 may communicate via an F1 interface according to a protocol that defines signaling messages (e.g., an F1 AP protocol). Additionally, or alternatively, the CU 160 may communicate with the core network via an interface, which may be an example of a portion of backhaul link, and may communicate with other CUs 160 (e.g., a CU 160 associated with an alternative IAB donor) via an Xn-C interface, which may be an example of a portion of a backhaul link.

An IAB node 104 may refer to a RAN node that provides IAB functionality (e.g., access for UEs 115, wireless self-backhauling capabilities). A DU 165 may act as a distributed scheduling node towards child nodes associated with the IAB node 104, and the IAB-MT may act as a scheduled node towards parent nodes associated with the IAB node 104. That is, an IAB donor may be referred to as a parent node in communication with one or more child nodes (e.g., an IAB donor may relay transmissions for UEs through one or more other IAB nodes 104). Additionally, or alternatively, an IAB node 104 may also be referred to as a parent node or a child node to other IAB nodes 104, depending on the relay chain or configuration of the AN. Therefore, the IAB-MT entity of IAB nodes 104 may provide a Uu interface for a child IAB node 104 to receive signaling from a parent IAB node 104, and the DU interface (e.g., DUs 165) may provide a Uu interface for a parent IAB node 104 to signal to a child IAB node 104 or UE 115.

For example, IAB node 104 may be referred to as a parent node that supports communications for a child IAB node, or referred to as a child IAB node associated with an IAB donor, or both. The IAB donor may include a CU 160 with a wired or wireless connection (e.g., a backhaul communication link 120) to the core network 130 and may act as parent node to IAB nodes 104. For example, the DU 165 of IAB donor may relay transmissions to UEs 115 through IAB nodes 104, or may directly signal transmissions to a UE 115, or both. The CU 160 of IAB donor may signal communication link establishment via an F1 interface to IAB nodes 104, and the IAB nodes 104 may schedule transmissions (e.g., transmissions to the UEs 115 relayed from the IAB donor) through the DUs 165. That is, data may be relayed to and from IAB nodes 104 via signaling via an NR Uu interface to MT of the IAB node 104. Communications with IAB node 104 may be scheduled by a DU 165 of IAB donor and communications with IAB node 104 may be scheduled by DU 165 of IAB node 104.

In the case of the techniques described herein applied in the context of a disaggregated RAN architecture, one or more components of the disaggregated RAN architecture may be configured to support techniques for iterative decoding using turbo spinal codes as described herein. For example, some operations described as being performed by a UE 115 or a network entity 105 (e.g., a base station 140) may additionally, or alternatively, be performed by one or more components of the disaggregated RAN architecture (e.g., IAB nodes 104, DUs 165, CUs 160, RUs 170, RIC 175, SMO 180).

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a tablet computer, a laptop computer, or a personal computer. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, or vehicles, meters, among other examples.

The UEs 115 described herein may be able to communicate with various types of devices, such as other UEs 115 that may sometimes act as relays as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via one or more communication links 125 (e.g., an access link) using resources associated with one or more carriers. The term “carrier” may refer to a set of RF spectrum resources having a defined physical layer structure for supporting the communication links 125. For example, a carrier used for a communication link 125 may include a portion of a RF spectrum band (e.g., a bandwidth part (BWP)) that is operated according to one or more physical layer channels for a given radio access technology (e.g., LTE, LTE-A, LTE-A Pro, NR). Each physical layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (e.g., entity, sub-entity) of a network entity 105. For example, the terms “transmitting,” “receiving,” or “communicating,” when referring to a network entity 105, may refer to any portion of a network entity 105 (e.g., a base station 140, a CU 160, a DU 165, a RU 170) of a RAN communicating with another device (e.g., directly or via one or more other network entities 105).

The communication links 125 shown in the wireless communications system 100 may include downlink transmissions (e.g., forward link transmissions) from a network entity 105 to a UE 115, uplink transmissions (e.g., return link transmissions) from a UE 115 to a network entity 105, or both, among other configurations of transmissions. Carriers may carry downlink or uplink communications (e.g., in an FDD mode) or may be configured to carry downlink and uplink communications (e.g., in a TDD mode).

A carrier may be associated with a particular bandwidth of the RF spectrum and, in some examples, the carrier bandwidth may be referred to as a “system bandwidth” of the carrier or the wireless communications system 100. For example, the carrier bandwidth may be one of a set of bandwidths for carriers of a particular radio access technology (e.g., 1.4, 3, 5, 10, 15, 20, 40, or 80 megahertz (MHz)). Devices of the wireless communications system 100 (e.g., the network entities 105, the UEs 115, or both) may have hardware configurations that support communications using a particular carrier bandwidth or may be configurable to support communications using one of a set of carrier bandwidths. In some examples, the wireless communications system 100 may include network entities 105 or UEs 115 that support concurrent communications using carriers associated with multiple carrier bandwidths. In some examples, each served UE 115 may be configured for operating using portions (e.g., a sub-band, a BWP) or all of a carrier bandwidth.

Signal waveforms transmitted via a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (e.g., a duration of one modulation symbol) and one subcarrier, in which case the symbol period and subcarrier spacing may be inversely related. The quantity of bits carried by each resource element may depend on the modulation scheme (e.g., the order of the modulation scheme, the coding rate of the modulation scheme, or both), such that a relatively higher quantity of resource elements (e.g., in a transmission duration) and a relatively higher order of a modulation scheme may correspond to a relatively higher rate of communication. A wireless communications resource may refer to a combination of an RF spectrum resource, a time resource, and a spatial resource (e.g., a spatial layer, a beam), and the use of multiple spatial resources may increase the data rate or data integrity for communications with a UE 115.

The time intervals for the network entities 105 or the UEs 115 may be expressed in multiples of a basic time unit which may, for example, refer to a sampling period of Tₛ=1/(Δfₘₐₓ·N_{f}) seconds, for which Δƒₘₐₓ may represent a supported subcarrier spacing, and N_{f} may represent a supported discrete Fourier transform (DFT) size. Time intervals of a communications resource may be organized according to radio frames each having a specified duration (e.g., 10 milliseconds (ms)). Each radio frame may be identified by a system frame number (SFN) (e.g., ranging from 0 to 1023).

Each frame may include multiple consecutively-numbered subframes or slots, and each subframe or slot may have the same duration. In some examples, a frame may be divided (e.g., in the time domain) into subframes, and each subframe may be further divided into a quantity of slots. Alternatively, each frame may include a variable quantity of slots, and the quantity of slots may depend on subcarrier spacing. Each slot may include a quantity of symbol periods (e.g., depending on the length of the cyclic prefix prepended to each symbol period). In some wireless communications systems 100, a slot may further be divided into multiple mini-slots associated with one or more symbols. Excluding the cyclic prefix, each symbol period may be associated with one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some examples, the TTI duration (e.g., a quantity of symbol periods in a TTI) may be variable. Additionally, or alternatively, the smallest scheduling unit of the wireless communications system 100 may be dynamically selected (e.g., in bursts of shortened TTIs (STTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a set of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (e.g., control channel elements (CCEs)) associated with encoded information for a control information format having a given payload size. Search space sets may include common search space sets configured for sending control information to multiple UEs 115 and UE-specific search space sets for sending control information to a specific UE 115.

In some examples, a network entity 105 (e.g., a base station 140, an RU 170) may be movable and therefore provide communication coverage for a moving coverage area 110. In some examples, different coverage areas 110 associated with different technologies may overlap, but the different coverage areas 110 may be supported by the same network entity 105. In some other examples, the overlapping coverage areas 110 associated with different technologies may be supported by different network entities 105. The wireless communications system 100 may include, for example, a heterogeneous network in which different types of the network entities 105 provide coverage for various coverage areas 110 using the same or different radio access technologies.

The wireless communications system 100 may support synchronous or asynchronous operation. For synchronous operation, network entities 105 (e.g., base stations 140) may have similar frame timings, and transmissions from different network entities 105 may be approximately aligned in time. For asynchronous operation, network entities 105 may have different frame timings, and transmissions from different network entities 105 may, in some examples, not be aligned in time. The techniques described herein may be used for either synchronous or asynchronous operations.

Some UEs 115 may be configured to employ operating modes that reduce power consumption, such as half-duplex communications (e.g., a mode that supports one-way communication via transmission or reception, but not transmission and reception concurrently). In some examples, half-duplex communications may be performed at a reduced peak rate. Other power conservation techniques for the UEs 115 include entering a power saving deep sleep mode when not engaging in active communications, operating using a limited bandwidth (e.g., according to narrowband communications), or a combination of these techniques. For example, some UEs 115 may be configured for operation using a narrowband protocol type that is associated with a defined portion or range (e.g., set of subcarriers or resource blocks (RBs)) within a carrier, within a guard-band of a carrier, or outside of a carrier.

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some examples, a UE 115 may be configured to support communicating directly with other UEs 115 via a device-to-device (D2D) communication link 135 (e.g., in accordance with a peer-to-peer (P2P), D2D, or sidelink protocol). In some examples, one or more UEs 115 of a group that are performing D2D communications may be within the coverage area 110 of a network entity 105 (e.g., a base station 140, an RU 170), which may support aspects of such D2D communications being configured by (e.g., scheduled by) the network entity 105. In some examples, one or more UEs 115 of such a group may be outside the coverage area 110 of a network entity 105 or may be otherwise unable to or not configured to receive transmissions from a network entity 105. In some examples, groups of the UEs 115 communicating via D2D communications may support a one-to-many (1:M) system in which each UE 115 transmits to each of the other UEs 115 in the group. In some examples, a network entity 105 may facilitate the scheduling of resources for D2D communications. In some other examples, D2D communications may be carried out between the UEs 115 without an involvement of a network entity 105.

In some systems, a D2D communication link 135 may be an example of a communication channel, such as a sidelink communication channel, between vehicles (e.g., UEs 115). In some examples, vehicles may communicate using vehicle-to-everything (V2X) communications, vehicle-to-vehicle (V2V) communications, or some combination of these. A vehicle may signal information related to traffic conditions, signal scheduling, weather, safety, emergencies, or any other information relevant to a V2X system. In some examples, vehicles in a V2X system may communicate with roadside infrastructure, such as roadside units, or with the network via one or more network nodes (e.g., network entities 105, base stations 140, RUs 170) using vehicle-to-network (V2N) communications, or with both.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (e.g., base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communications using UHF waves may be associated with smaller antennas and shorter ranges (e.g., less than 100 kilometers) compared to communications using the smaller frequencies and longer waves of the high frequency (HF) or very high frequency (VHF) portion of the spectrum below 300 MHz.

The wireless communications system 100 may also operate using a super high frequency (SHF) region, which may be in the range of 3 GHz to 30 GHZ, also known as the centimeter band, or using an extremely high frequency (EHF) region of the spectrum (e.g., from 30 GHz to 300 GHz), also known as the millimeter band. In some examples, the wireless communications system 100 may support millimeter wave (mmW) communications between the UEs 115 and the network entities 105 (e.g., base stations 140, RUs 170), and EHF antennas of the respective devices may be smaller and more closely spaced than UHF antennas. In some examples, such techniques may facilitate using antenna arrays within a device. The propagation of EHF transmissions, however, may be subject to even greater attenuation and shorter range than SHF or UHF transmissions. The techniques disclosed herein may be employed across transmissions that use one or more different frequency regions, and designated use of bands across these frequency regions may differ by country or regulating body.

The wireless communications system 100 may utilize both licensed and unlicensed RF spectrum bands. For example, the wireless communications system 100 may employ License Assisted Access (LAA), LTE-Unlicensed (LTE-U) radio access technology, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some examples, operations using unlicensed bands may be based on a carrier aggregation configuration in conjunction with component carriers operating using a licensed band (e.g., LAA). Operations using unlicensed spectrum may include downlink transmissions, uplink transmissions, P2P transmissions, or D2D transmissions, among other examples.

A network entity 105 (e.g., a base station 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

The network entities 105 or the UEs 115 may use MIMO communications to exploit multipath signal propagation and increase spectral efficiency by transmitting or receiving multiple signals via different spatial layers. Such techniques may be referred to as spatial multiplexing. The multiple signals may, for example, be transmitted by the transmitting device via different antennas or different combinations of antennas. Likewise, the multiple signals may be received by the receiving device via different antennas or different combinations of antennas. Each of the multiple signals may be referred to as a separate spatial stream and may carry information associated with the same data stream (e.g., the same codeword) or different data streams (e.g., different codewords). Different spatial layers may be associated with different antenna ports used for channel measurement and reporting. MIMO techniques include single-user MIMO (SU-MIMO), for which multiple spatial layers are transmitted to the same receiving device, and multiple-user MIMO (MU-MIMO), for which multiple spatial layers are transmitted to multiple devices.

Beamforming, which may also be referred to as spatial filtering, directional transmission, or directional reception, is a signal processing technique that may be used at a transmitting device or a receiving device (e.g., a network entity 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

A network entity 105 or a UE 115 may use beam sweeping techniques as part of beamforming operations. For example, a network entity 105 (e.g., a base station 140, an RU 170) may use multiple antennas or antenna arrays (e.g., antenna panels) to conduct beamforming operations for directional communications with a UE 115. Some signals (e.g., synchronization signals, reference signals, beam selection signals, or other control signals) may be transmitted by a network entity 105 multiple times along different directions. For example, the network entity 105 may transmit a signal according to different beamforming weight sets associated with different directions of transmission. Transmissions along different beam directions may be used to identify (e.g., by a transmitting device, such as a network entity 105, or by a receiving device, such as a UE 115) a beam direction for later transmission or reception by the network entity 105.

Some signals, such as data signals associated with a particular receiving device, may be transmitted by transmitting device (e.g., a transmitting network entity 105, a transmitting UE 115) along a single beam direction (e.g., a direction associated with the receiving device, such as a receiving network entity 105 or a receiving UE 115). In some examples, the beam direction associated with transmissions along a single beam direction may be determined based on a signal that was transmitted along one or more beam directions. For example, a UE 115 may receive one or more of the signals transmitted by the network entity 105 along different directions and may report to the network entity 105 an indication of the signal that the UE 115 received with a highest signal quality or an otherwise acceptable signal quality.

In some examples, transmissions by a device (e.g., by a network entity 105 or a UE 115) may be performed using multiple beam directions, and the device may use a combination of digital precoding or beamforming to generate a combined beam for transmission (e.g., from a network entity 105 to a UE 115). The UE 115 may report feedback that indicates precoding weights for one or more beam directions, and the feedback may correspond to a configured set of beams across a system bandwidth or one or more sub-bands. The network entity 105 may transmit a reference signal (e.g., a cell-specific reference signal (CRS), a channel state information reference signal (CSI-RS)), which may be precoded or unprecoded. The UE 115 may provide feedback for beam selection, which may be a precoding matrix indicator (PMI) or codebook-based feedback (e.g., a multi-panel type codebook, a linear combination type codebook, a port selection type codebook). Although these techniques are described with reference to signals transmitted along one or more directions by a network entity 105 (e.g., a base station 140, an RU 170), a UE 115 may employ similar techniques for transmitting signals multiple times along different directions (e.g., for identifying a beam direction for subsequent transmission or reception by the UE 115) or for transmitting a signal along a single direction (e.g., for transmitting data to a receiving device).

A receiving device (e.g., a UE 115) may perform reception operations in accordance with multiple receive configurations (e.g., directional listening) when receiving various signals from a receiving device (e.g., a network entity 105), such as synchronization signals, reference signals, beam selection signals, or other control signals. For example, a receiving device may perform reception in accordance with multiple receive directions by receiving via different antenna subarrays, by processing received signals according to different antenna subarrays, by receiving according to different receive beamforming weight sets (e.g., different directional listening weight sets) applied to signals received at multiple antenna elements of an antenna array, or by processing received signals according to different receive beamforming weight sets applied to signals received at multiple antenna elements of an antenna array, any of which may be referred to as “listening” according to different receive configurations or receive directions. In some examples, a receiving device may use a single receive configuration to receive along a single beam direction (e.g., when receiving a data signal). The single receive configuration may be aligned along a beam direction determined based on listening according to different receive configuration directions (e.g., a beam direction determined to have a highest signal strength, highest signal-to-noise ratio (SNR), or otherwise acceptable signal quality based on listening according to multiple beam directions).

The UEs 115 and the network entities 105 may support retransmissions of data to increase the likelihood that data is received successfully. Hybrid automatic repeat request (HARQ) feedback is one technique for increasing the likelihood that data is received correctly via a communication link (e.g., a communication link 125, a D2D communication link 135). HARQ may include a combination of error detection (e.g., using a cyclic redundancy check (CRC)), forward error correction (FEC), and retransmission (e.g., automatic repeat request (ARQ)). HARQ may improve throughput at the MAC layer in poor radio conditions (e.g., low signal-to-noise conditions). In some examples, a device may support same-slot HARQ feedback, in which case the device may provide HARQ feedback in a specific slot for data received via a previous symbol in the slot. In some other examples, the device may provide HARQ feedback in a subsequent slot, or according to some other time interval.

In the wireless communications system 100, a receiving device (e.g., UE 115, network entity 105) and a transmitting device (e.g., UE 115, network entity 105) may encode or decode a message using a rateless coding scheme, such as a spinal coding scheme. For instance, the transmitting device partition a message into submessages, where each submessage includes a set of bits. Additionally, the transmitting device may set or configure an initial state, a seed value, or some other parameter to a value. As part of the spinal coding scheme, the transmitting device may encode the message across multiple stages in accordance with the initial state and the submessages, where the first stage involves an encoding for an initial submessage and each subsequent stage involves an encoding for an additional submessage. Because each stage of the spinal coding scheme may output a new seed value for a subsequent stage of the spinal coding scheme in accordance with the encoding for the current stage, the spinal coding scheme may be a convolutional type of coding scheme.

For each stage of the spinal coding scheme, the transmitting device may use a hash function and an RNG to generate a rateless encoder output for each submessage. For instance, in a first stage of the spinal coding scheme, the transmitting device may apply the hash function to an initial state and a first submessage to output a pseudo-random seed value to be used for a second stage of the spinal coding scheme. Additionally, an RNG may obtain the outputted seed value as an input to the RNG to generate infinite pseudo-random sequences associated with the first submessage. The transmitting device may continue encoding the remaining submessages of the message in a similar manner until the submessages are encoded. Because each submessage may be associated with a rateless encoder output, the transmitting device may perform encoding with a spinal code that has an unlimited constraint length. Additionally, because the transmitting device may apply the hash function to different inputs, the rateless encoder outputs for the submessages may be substantially different.

In some cases, the receiving device and the transmitting device may encode or decode a message using a turbo coding scheme that includes two separate spinal codes and an interleaver, where the interleaver generates inputs for a second spinal code based on inputs of a first spinal code. For instance, the transmitting device may use a two-way spinal interleaver to generate submessage inputs for the second spinal code that are the reverse of submessage inputs for the first spinal code, allowing for the transmitting device to perform forward and backward encoding with the turbo spinal code. In some cases, the interleaver used for decoding or encoding a message may cause the receiving device and the transmitting device to perform decoding, encoding, or both with less overhead. However, it is desired for a receiving device to reduce signaling overhead to further improve the decoding performance of the receiving device.

In accordance with one or more aspects of the present disclosure, a receiving device or a transmitting device (e.g., UE 115 or network entity 105) may improve the decoding performance of the receiving device by supporting iterative decoding techniques for turbo spinal codes. For example, the receiving device may decode a message iteratively using a turbo spinal code that includes a first decoder, a first interleaver, a second decoder, and a second interleaver (e.g., a deinterleaver). In some aspects, the receiving device may use an iterative list decoding technique to generate a reduced quantity of submessage candidates with each decoding iteration of the turbo spinal code, where the submessage candidates generated for a subsequent iteration is based on that of a preceding iteration. Additionally, or alternatively, the receiving device may use a soft decoding technique to generate soft information for a respective submessage with each decoding iteration of the turbo spinal code, where the soft information generated in a subsequent iteration is based on that of a preceding iteration. In some aspects, the first interleaver, the second interleaver, or both, may be a rectangular interleaver (e.g., row-in column-out rectangular interleaver), triangular interleaver (e.g., 5G for polar code), pseudo-random interleaver, or a two-way spinal interleaver.

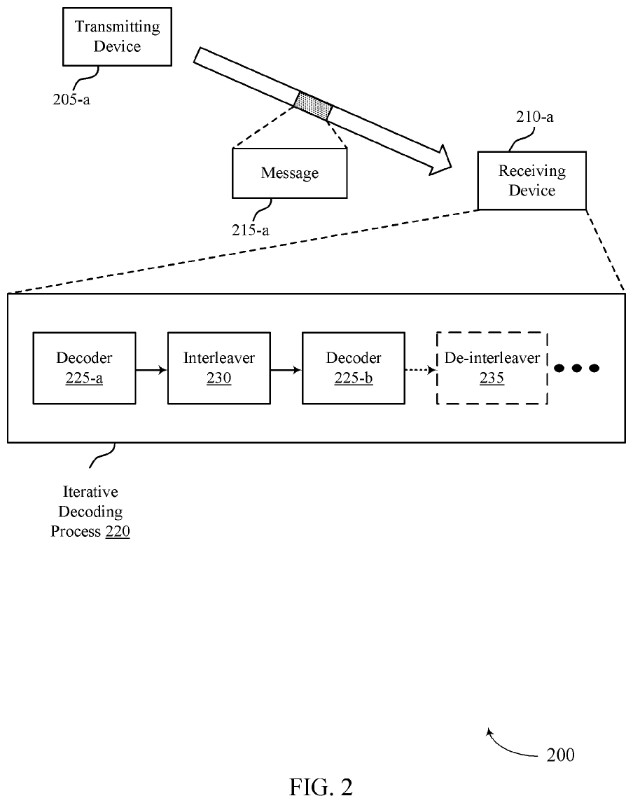

FIG. 2 illustrates an example of a wireless communications system 200 that supports techniques for iterative decoding using turbo spinal codes in accordance with one or more aspects of the present disclosure. The wireless communications system 200 may implement or be implemented to realize aspects of the wireless communications system 100. For example, the wireless communications system 200 may include a transmitting device 205-a (such as an encoding device) and a receiving device 210-a (such as a decoding device), which may be examples of the UE 115 and the network entity 105, or vice versa, as described with reference to FIG. 1. The transmitting device 205-a may be an example of any device capable of wireless communications and, as such, may be an example of any device which may perform one or more aspects of encoding and transmitting a message in accordance with examples as disclosed herein. The receiving device 210-a may be an example of any device capable of wireless communications and, as such, may be an example of any device which may perform one or more aspects of receiving and decoding a message in accordance with examples as disclosed herein.

In some implementations, the transmitting device 205-a and the receiving device 210-a may support a rateless coding scheme, such as a turbo spinal coding scheme, for encoding or decoding a message 215-a. For example, the transmitting device 205-a may transmit the message 215-a to the receiving device 210-a, where the message 215-a includes a set of bits partitioned into a set of submessages. The message 215-a may be partitioned into M submessages, where M=n/k (n is the quantity of bits in the message 215-a, and k is the quantity of bits in each submessage). In some examples, the transmitting device 205-a may encode the message 215-a using a turbo spinal code before transmitting the message 215-a to the receiving device 210-a. In such examples, the message 215-a may include a set of submessages (e.g., encoded submessages), where each submessage includes a set of pseudo-random sequences. An encoder of the transmitting device 205-a may output the set of pseudo-random sequences (e.g., encoded outputs) for each submessage when encoding the message 215-a.

In some examples, the receiving device 210-a may decode the message 215-a using an iterative decoding process 220. In the iterative decoding process 220, the receiving device 210-a may use two turbo spinal codes. The receiving device 210-a may use a decoder 225-a (e.g., a first decoder), an interleaver 230 (e.g., a first interleaver), a decoder 225-b (e.g., a second decoder), and a deinterleaver 235 (e.g., a second interleaver) to decode each submessage of the message 215-a. The interleaver 230, the deinterleaver 235, or both, may be a row-in column-out rectangular interleaver, a triangular interleaver, a pseudo-random interleaver, or a two-way spinal interleaver. In some examples, the deinterleaver 235 may be a second interleaver that is associated with the interleaver 230. For instance, if the interleaver 230 is a two-way spinal interleaver, the deinterleaver 235 may also be a two-way spinal interleaver. Additionally, or alternatively, the decoder 225-b may be associated with the decoder 225-a. For instance, the decoder 225-b may be the same type of decoder as the decoder 225-a.

In some implementations, the receiving device 210-a may perform the iterative decoding process 220 using a list decoding algorithm. For example, the decoder 225-a may be a first list decoder (e.g., a first bubble decoder) and the decoder 225-b may be a second list decoder (a second bubble decoder). If the list decoding algorithm is used for decoding, the decoder 225-a may be associated with a first spinal code tree, and the decoder 225-b may be associated with a second spinal code tree. In some cases, the receiving device 210-a may perform quadrature amplitude modulation (QAM) demodulation on measured in-phase and quadrature components of a transmitted wave (e.g., a QAM value) carrying the encoded message 215-a, and the receiving device 210-a may obtain bits (e.g., a received demodulated QAM value) corresponding to the encoded outputs. In such cases, the received demodulated QAM value for the encoded outputs of the message 215-a may be the input for the iterative decoding process 220.

Upon receiving the message 215-a, the receiving device 210-a may perform a first list search operation to generate a first set of submessage candidates using the first spinal code tree. For example, the receiving device 210-a may begin the iterative decoding process 220 by inputting an initial input to the decoder 225-a. In accordance with the initial input, the decoder 225-a may generate a first set of submessage candidates. For instance, the decoder 225-a may exponentially generate submessage candidates for each node of the first spinal code tree based on the initial input and parameters set for the receiving device 210-a until the first set of submessage candidates are entirely generated. As such, for the case of the previous example, the decoder 225-a may output the first set of submessage candidates.

Additionally, the receiving device 210-a may interleave the first set of submessage candidates using the interleaver 230 to generate a set of interleaved submessage candidates. For instance, for the case of the previous example, the decoder 225-a may input the first set of submessage candidates into the interleaver 230, and the interleaver 230 may output the set of interleaved submessage candidates. In some examples, the receiving device 210-a may perform a second list search operation associated with the second spinal code tree on the set of interleaved submessage candidates to generate a second set of submessage candidates. For instance, when performing the second list search operation, the receiving device 210-a may input the set of interleaved submessage candidates into the decoder 225-b, and the decoder 225-b may generate the second set of submessage candidates. The receiving device 210-a may decode the message 215-a (including the encoded submessages) based on the first set of submessage candidates from the first spinal code tree and the second set of submessage candidates from the second spinal code tree.

In some examples, the receiving device 210-a may refrain from including one or more submessage candidates in the second set of submessage candidates based on determining that the one or more submessage candidates fail to satisfy a path metric. The path metric may convey a path cost that indicates a quality of decoding for a potential path within a spinal code tree, where the potential path includes a subset of submessage candidates of the set of submessage candidates. Typically, lower path costs may be associated with a higher quality of decoding than higher path costs. Accordingly, the receiving device 210-a may determine that a potential path of the second spinal code tree fails to meet the path metric, and the receiving device 210-a may eliminate one or more submessage candidates of the potential path failing to meet the path metric from the second set of submessage candidates. As such, the second set of submessage candidates from the second spinal code tree may include less submessage candidates than the first set of submessage candidates from the first spinal code tree.

In some examples, the receiving device 210-a may perform a second iteration of the first list search operation associated with the first spinal code tree. For example, the receiving device 210-a may input the second set of submessage candidates to the deinterleaver 235 to generate an input for a second iteration of the first list operation and continue the iterative decoding process 220. The receiving device 210-a may continue the iterative decoding process 220 until one submessage candidate remains in the second set of submessage candidates or until a maximum iteration threshold is reached. For instance, in some aspects, the receiving device 210-a may terminate the iterative decoding process 220 for list decoding based on determining that the quantity of submessage candidates of the second set of submessage candidates is equal to one. Additionally, or alternatively, the receiving device 210-a may perform a CRC on a last iteration (e.g., at the maximum iteration) of the iterative decoding process 220 based on a message candidate, where the message candidate corresponds to a first submessage candidate of the first set of submessage candidates and a second submessage candidate of the second set of submessage candidates. In some cases, the receiving device 210-a may terminate the iterative decoding process 220 for list decoding based on a success of the CRC.

In some implementations, the receiving device 210-a may perform the iterative decoding process 220 using a soft decoding algorithm. For example, the decoder 225-a may be a first soft decoder, and the decoder 225-b may be a second soft decoder. After receiving the message 215-a, the receiving device 210-a may perform a first soft decoding operation to generate a first set of soft information, where the first set of soft information indicates a probability that a first estimation of the submessage is correctly estimated by the receiving device 210-a. For example, the receiving device 210-a may begin the iterative decoding process 220 by inputting an initial input (e.g., a first estimation of the submessage) to the decoder 225-a. In accordance with the initial input, the decoder 225-a may output the first set of soft information. In some examples, the receiving device 210-a may determine a first log likelihood ratio (LLR) based on the first set of soft information, where the first LLR indicates a fit for the first estimation of the submessage. In some aspects, a higher LLR may indicate a better fit than a lower LLR.

Additionally, the receiving device 210-a may interleave the first set of soft information using the interleaver 230 to generate a set of interleaved soft information. For instance, for the case of the previous example, the decoder 225-a may input the first set of soft information to the interleaver 230, and the interleaver 230 may output the set of interleaved soft information. In some examples, the receiving device 210-a may perform a second soft decoding operation on the set of interleaved soft information to generate a second set of soft information, where the second set of soft information indicates a probability that a second estimation of the submessage is correctly estimated by the receiving device 210-a. For instance, when performing the second soft decoding operation, the receiving device 210-a may input the set of interleaved soft information to the decoder 225-b, and the decoder 225-b may generate the second set of soft information for a second estimation of the submessage. In some examples, the receiving device 210-a may determine a second LLR based on the second set of soft information. In some cases, the second set of soft information may be different from or the same as the first set of soft information. Additionally, or alternatively, the second LLR may be different from or the same as the first LLR. In some examples, the second estimation of the submessage may be more correct than the first estimation of the submessage if the second LLR is greater than the first LLR.

The receiving device 210-a may decode the message 215-a (including the encoded submessages) based on the first set of soft information and the second set of soft information. Additionally, or alternatively, the receiving device 210-a may decode the message 215-a based on the first LLR and the second LLR. For example, if the second LLR is greater than the second LLR, the receiving device 210-a may decode the message 215-a such that the decoded submessage of the message 215-a is more similar to the second estimation of the submessage than the first estimation of the submessage.

In some examples, the receiving device 210-a may perform a next iteration of the first soft decoding operation. For example, the receiving device 210-a may input the second set of soft information to the deinterleaver 235 to generate an input for a second iteration of the first list operation and continue the iterative decoding process 220. The receiving device 210-a may continue the iterative decoding process 220 until meeting the maximum iteration threshold, after which the receiving device 210-a may perform the CRC based on a message candidate corresponding to the first and second sets of soft information and terminate the iterative decoding process 220 based on the success of the CRC.

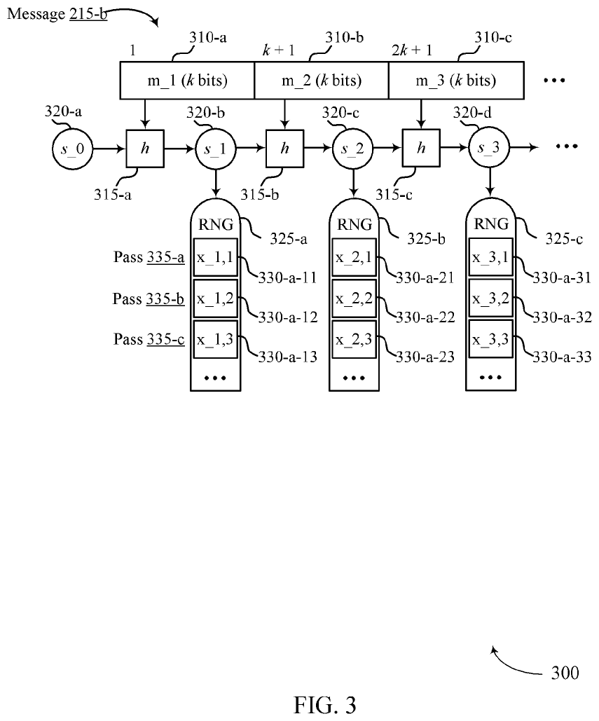

FIG. 3 illustrates an example of a spinal coding scheme 300 that supports techniques for iterative decoding using turbo spinal codes in accordance with one or more aspects of the present disclosure. The spinal coding scheme 300 may be implemented to realize aspects of the wireless communications system 100 and the wireless communications system 200. For example, the spinal coding scheme 300 illustrates a sequential or cumulative coding of a message 215-b, such as a sequential or cumulative encoding of submessages 310. In some implementations, an encoder of a transmitting device 205 may employ the spinal coding scheme 300 to encode the message 215-b and may transmit the encoded message 215-b to a receiving device 210. After receiving the encoded message 215-b, the receiving device 210 may decode the encoded message 215-b with iterative decoding techniques.

The spinal coding scheme 300 may illustrate a spinal coding technique. Spinal codes may be a class of rateless codes that are compatible with time-varying channel conditions in a natural or simple way without use of an explicit bit rate selection. In other words, rateless coding, such as spinal coding, may be associated with an absence or lack of explicit signaling for bit rates of a transmission. For example, communicating devices may refrain from transmitting an indication of one or more aspects of an MCS while implementing rateless coding. Instead, a transmitting device 205 may use rateless codes, such as spinal codes, to perform an initial transmission of a message 215-b at a high bit rate (e.g., a relatively highest bit rate) and, if one or more NACKs associated with the message 215-b are received from a receiving device 210, to perform iterative transmission of additional information associated with the message via one or more additional transmissions (such as retransmissions), which may lower an effective bit rate until the receiving device 210 is able to successfully decode the message (such as until the transmitting device 205 receives an ACK associated with the message 215-b).

In accordance with encoding techniques that implement spinal codes, a transmitting device 205 may perform the encoding of the message 215-b. As part of the spinal coding scheme 300, a transmitting device 205 may apply a hash function 315 (such as a random hash function) sequentially or cumulatively to bits of a message 215-b (such as segments or portions of the message 215-b) to produce a sequence of coded bits and symbols (such as modulation symbols) for transmission. In some aspects, the transmitting device 205 may employ the encoding such that two input messages that differ in even one bit may lead to different coded sequences after a point at which the two input messages differ, which may provide resilience to noise or bit errors.

As such, the spinal coding scheme 300 may involve or pertain to a cumulative or sequential encoding of a message 215-b across a set of submessages 310. For example, as part of the spinal coding scheme 300, a transmitting device 205 may partition or segment the message 215-b into a set of submessages 310 and may cumulatively encode the message 215-b across multiple stages of the spinal coding scheme 300 (each stage involving an encoding of a next submessage 310). In some aspects, a message 215-b may include a quantity of n bits and a transmitting device 205 may partition or segment the message 215-b into a set of submessages 310 such that each submessage (e.g., message segment) includes k bits. In various implementations, k may be the same for each submessage 310 or may be different for some submessages 310 (such that some submessages 310 may include different quantities of bits than other submessages 310). In some aspects, and in accordance with the spinal coding scheme 300 being associated with a lack of an explicit bit rate selection, the spinal coding scheme 300 may be associated with a non-selection (by communicating devices) of the k and n parameters (as the k and n parameters may influence the bit rate of the message 215-b). The set of submessages 310 may accordingly include a quantity of n/k submessages 310.

For example, a transmitting device 205 may partition the message 215-b into a submessage 310-a (which may be referred to or denoted as a submessage m₁ or m_1) starting at bit 1 of the message 215-b, a submessage 310-b (which may be referred to or denoted as a submessage m₂ or m_2) starting at bit k+1 of the message 215-b, a submessage 310-c (which may be referred to or denoted as a submessage m₃ or m_3) starting at bit 2k+1 of the message 215-b, and so on for each submessage 310 of the message 215-b. An encoder of the transmitting device 205 may include, for each stage of the spinal coding scheme 300, a hash function 315 and a numeric transposition function, such as an RNG 325 or other scrambling function. The hash functions 315 and the RNGs 325 of the spinal coding scheme 300 may be known to both a transmitting device 205 and a receiving device 210. For example, the hash functions 315 and the RNGs 325 may be pre-configured (such as pre-loaded) at both a transmitting device 205 and a receiving device 210, or one or more aspects or configurations of such functions may be signaled between a transmitting device 205 and a receiving device 210. In some aspects, an encoder of a transmitting device 205 or a decoder of a receiving device 210, or both, may combine a hash function 315 with an RNG 325 into a single or same processing block. Moreover, although each instance of a hash function 315 and each instance of an RNG 325 are illustrated separately, in some implementations, the separately illustrated instances of a hash function 315, or an RNG 325, or both may be performed by a same set of functional instructions, or by a same set of processing circuitry, which may be performed with different inputs to provide different outputs.

A transmitting device 205 may implement a hash function 315 with two inputs including a spine 320 (which may be referred to as an encoded value and may be an example of a v bit state) and a submessage 310 (which may include a portion, chunk, or quantity of k bits of the message 215-b) and may obtain, as an output of a hash function 315, a new spine 320 (a new encoded value or a new v bit state). Thus, a hash function 315 may obtain a first input (a spine 320) of size v bits and a second input (a submessage 310) of size k bits and may output a spine 320 of size v bits. In some aspects, s₀ (or s_0) may be an initial input spine 320-a or some other initial value and may be set equal to zero, or to some other default or pre-configured value. Additionally, or alternatively, a transmitting device 205 and a receiving device 210 may coordinate (such as via an exchange of one or more signals) on a value of s₀.

A transmitting device 205 may generate a spine 320 of v bit states by sequentially or cumulatively hashing together groups of k bits from the input message 215-b. For example, a transmitting device 205 may obtain a spine 320-b as an output of a hash function 315-a, may obtain a spine 320-c as an output of a hash function 315-b, and may obtain a spine 320-d as an output of a hash function 315-c. Further, in some aspects, a transmitting device 205 may use or otherwise reach a hash function 315 with a low probability of hash collisions (in part as a result of the sequential or cumulative hashing of groups or segments of k bits from the input message 215-b).

The transmitting device 205 may generate a spine 320 for each message 310 and may use each of the n/k spines 320 as a seed or input into a respective instance of an RNG 325. A spine 320 may include or otherwise convey information associated with a submessage 310 of a same coding indices or stage as well as information associated with submessages 310 of preceding coding indices or stages. For instance, the spine 320-b may include or otherwise convey information associated with the submessage 310-a (and a seed value so, such as a device identifier, where applicable), the spine 320-c may include or otherwise convey information associated with the submessage 310-a and the submessage 310-b, and the spine 320-d may include or otherwise convey information associated with the submessage 310-a, the submessage 310-b, and the submessage 310-c. As such, a last or final spine 320 may include encoded information associated with the entire message 215-b and a transmitting device 205 may, in some scenarios, transmit a signal associated with the last spine 320 (and suppress transmission of signals associated with other spines 320) to achieve an upper limit bit or channel rate (because the transmission of the signal associated with the last spine 320 may convey the entire message 215-b via a single channel use).

Each instance of an RNG 325, in accordance with receiving a spine 320 as an input, may output a symbol value 330 (such as a sequence of numbers or a sequence of bits). As such, an RNG 325 may obtain a value of a spine 320 as an input (having a size of v bits) and may apply some numeric transposition function to the value of the spine 320. Such a numeric transposition function may be an RNG, a pseudo-random RNG, a mapping function, a scrambling function, a scaling function, or any combination thereof. In some implementations, a symbol value 330 may be an example of, or may be otherwise associated with (such as mapped to) one or more modulation symbols. In implementations, the transmitting device 205 may use a mapping function to generate a transmitted symbol (such as a modulation symbol) from an output of an RNG 325. In such implementations, a transmitting device 205 may use the mapping function to map each symbol value 330 to a (different) modulation symbol.

In some implementations, a transmitting device 205 may achieve higher bit rates (without increasing a decoding cost) via a puncturing of the transmitted symbols at the transmitter side, where such transmission puncturing may refer to various techniques for performing transmissions associated with a subset of the spines 320 for a given message 215-b, such as refraining from performing transmissions associated with one or more spines 320 for at least in an initial transmission associated with the given message 215-b. For example, a transmitting device 205 may transmit one or more signals associated with one or more specific spines 320 over a set of passes 335. For example, a transmitting device 205 may transmit a signal associated with the spine 320-d during a pass 335-a, may transmit a signal associated with the spine 320-c during a pass 335-b, and may transmit a signal associated with the spine 320-b during a pass 335-c, where applicable.

Further, and as shown in the spinal coding scheme 300, a transmitting device 205 may obtain a symbol value 330 (e.g., encoder output) from each RNG 325 in accordance with a pass 335. For instance, the RNG 325-a may output rateless symbol values 330 (e.g., an infinite quantity of encoded outputs) for the input spine 320-b, rateless symbol values 330 for the input spine 320-c, and rateless symbol values 330 for the input spine 320-d. In some examples, the RNG 325-a may output a symbol value 330-a-11 (as illustrated by or denoted as an x_{1,1} or x_1,1 value) for the pass 335-a, a symbol value 330-a-12 (as illustrated by or denoted as an x_{1,2} or x_1,2 value) for the pass 335-b, a symbol value 330-a-13 (as illustrated by or denoted as an x_{1,3} or x_1,3 value) for the pass 335-c, and other symbol values 330 for other passes 335. Additionally, the RNG 325-b may output, for the input spine 320-c, a symbol value 330-a-21 (as illustrated by or denoted as an x_{2,1} or x_2,1 value) for the pass 335-a, a symbol value 330-a-22 (as illustrated by or denoted as an x_{2,2} or x_2,2 value) for the pass 335-b, a symbol value 330-a-23 (as illustrated by or denoted as an x_{2,3} or x_2,3 value) for the pass 335-c, and other symbol values 330 for other passes 335. Additionally, the RNG 325-c may output, for the input spine 320-d, a symbol value 330-a-31 (as illustrated by or denoted as an x_{3,1} or x_3,1 value) for the pass 335-a, a symbol value 330-a-32 (as illustrated by or denoted as an x_{3,2} or x_3,2 value) for the pass 335-b, a symbol value 330-a-33 (as illustrated by or denoted as an x_{3,3} or x_3,3 value) for the pass 335-c, and other symbol values 330 for other passes 335. Although a symbol value 330 is illustrated for each spine 320 at each pass 335, a transmitting device 205 may refrain from generating those symbol values 330 that are not configured or scheduled for transmission, such as those spines 320 that have been punctured by a transmission puncturing scheme for a given pass 335.

As such, if the transmitting device 205 transmits a signal associated with the spine 320-d during the pass 335-a, transmits a signal associated with the spine 320-c during the pass 335-b, and transmits a signal associated with the spine 320-b during the pass 335-c, the transmitting device 205 may transmit a signal associated with the symbol value 330-a-31 during the pass 335-a, a signal associated with the symbol value 330-a-22 during the pass 335-b, and a signal associated with the symbol value 330-a-13 during the pass 335-c.

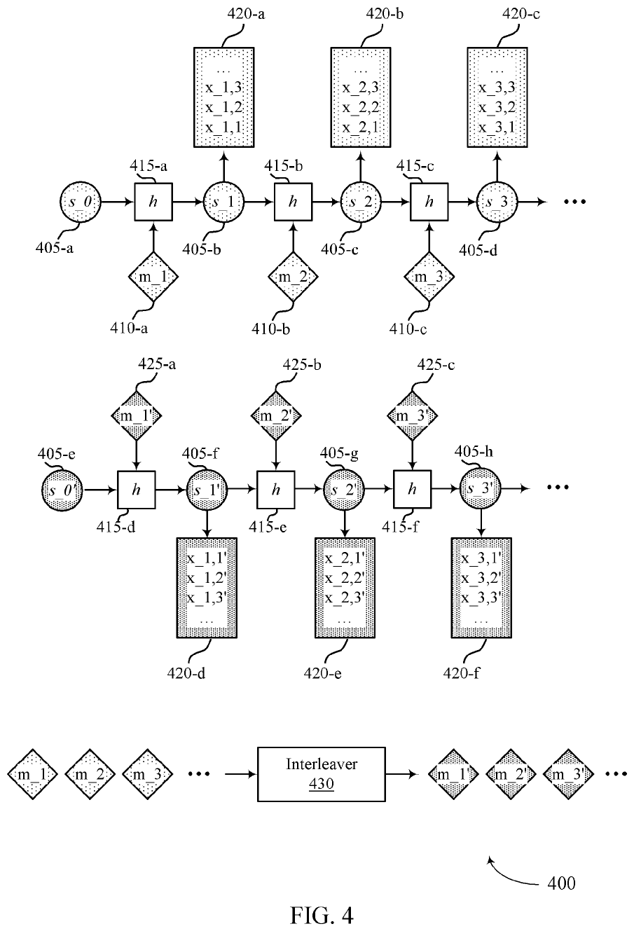

FIG. 4 illustrates an example of a turbo spinal coding scheme 400 that supports techniques for iterative decoding using turbo spinal codes in accordance with one or more aspects of the present disclosure. The turbo spinal coding scheme 400 may be implemented to realize aspects of the wireless communications system 100 and the wireless communications system 200. For example, the turbo spinal coding scheme 400 illustrates a sequential or cumulative encoding of a message. In some implementations, an encoder of a transmitting device 205 may employ the turbo spinal coding scheme 400 to encode the message and may transmit the encoded message to a receiving device 210. After receiving the encoded message, the receiving device 210 may decode the encoded message with iterative decoding techniques.

The turbo spinal coding scheme 400 illustrated in FIG. 4 may involve a cumulative or sequential encoding of a message across a set of submessages, where an interleaver 430 generates interleaved submessages 425 from submessages 410 to allow for encoding of the interleaved submessages 425 in addition to encoding of the submessages 410. For instance, the turbo spinal coding scheme 400 may include a first spinal code for a first encoding of a message and a second spinal code for a second encoding of the message, where the second encoding may be treated as an information pass through the interleaver 430 followed by the first encoding.

For example, a transmitting device 205 may partition a message into a submessage 410-a (which may be referred to or denoted as a submessage m₁ or m_1), a submessage 410-b (which may be referred to or denoted as a submessage m₂ or m_2), a submessage 410-c (which may be referred to or denoted as a submessage m₃ or m_3), and so on for each submessage 410 of the message. Additionally, the transmitting device 205 may input the submessage 410-a, the submessage 410-b, and the submessage 410-c into the interleaver 430 to generate an interleaved submessage 425-a (which may be referred to or denoted as a submessage m₁′ or m_1′), an interleaved submessage 425-b (which may be referred to or denoted as a submessage m₂′ or m_2′), and an interleaved submessage 425-c (which may be referred to or denoted as a submessage m₃′ or m_3′), where the interleaved submessages 425 are interleavings (e.g., arrangements, scramblings, etc.) of the submessages 410. In some examples, the interleaver 430 may be a row-in column-out rectangular interleaver, a triangular interleaver (similar to 5G for polar code), a pseudo-random interleaver, or a two-way spinal interleaver. If the interleaver 430 is a two-way spinal interleaver, the interleaved submessage 425-a may be a reverse arrangement of the submessage 410-a (e.g., n, n−1, n−2, . . . , 2, 1, 0), the interleaved submessage 425-b may be a reverse arrangement of the submessage 410-b, and the interleaved submessage 425-c may be a reverse arrangement of the submessage 410-c. If the interleaver 430 is a pseudo-random interleaver, the interleaved submessages 425 may be pseudo-random scramblings of the respective submessages 410 (e.g., statistically randomly arranged in accordance with an algorithms).

In some examples, s₀ (or s_0) may be an initial input spine 405-a that begins encoding on the first spinal code tree, and s̅₀ (or s_0′) may be an initial input spine 405-e that begins encoding on the second spinal code tree. In accordance with the initial input spine 405-a, a transmitting device 205 may obtain a spine 405-b as an output of a hash function 415-a, may obtain a spine 405-c as an output of a hash function 415-b, and may obtain a spine 405-d as an output of a hash function 415-c. In accordance with the initial input spine 405-e, a transmitting device 205 may obtain a spine 405-f as an output of a hash function 415-d, may obtain a spine 405-g as an output of a hash function 415-e, and may obtain a spine 405-h as an output of a hash function 415-f.

The transmitting device 205 may use the spines 405-a, 405-b, 405-c, and 405-d to generate a first rateless set of symbol values 420-a, 420-b, and 420-c (such as a sequence of numbers or a sequence of bits), and the transmitting device 205 may use the spines 405-e, 405-f, and 405-g, and 405-h to generate a second set of rateless symbol values 420-d, 420-e, and 420-f. As such, a transmitting device 205 may encode a message by obtaining rateless symbol values 420. For example, an RNG for the input spine 405-b may output a set of symbol values 420-a (as illustrated by x_1,1, x_1,2, and x_1,3), the RNG for the input spine 405-c may output a set of symbol values 420-b (as illustrated by x_2,1, x_2,2, and x_2,3), and the RNG for the input spine 405-c may output a set of symbol values 420-c (as illustrated by x_3,1, x_3,2, and x_3,3). Additionally, an RNG for the input spine 405-f may output a set of symbol values 420-d (as illustrated by x_1,1′, x_1,2′, and x_1,3′), the RNG for the input spine 405-g may output a set of symbol values 420-e (as illustrated by x_2,1′, x_2,2′, and x_2,3′), and the RNG for the input spine 405-g may output a set of symbol values 420-f (as illustrated by x_3,1′, x_3,2′, and x_3,3′). Because the transmitting device 205 is able to output the sets of symbol values 420-d, 420-e, and 420-f in addition to the sets of symbol values 420-a, 420-b, and 420-c when using the turbo spinal coding scheme 400, the transmitting device 205 may iteratively decode a message with reduced overhead than with the spinal coding scheme 300 since fewer passes may be used to iteratively decode with the turbo spinal coding scheme 400.

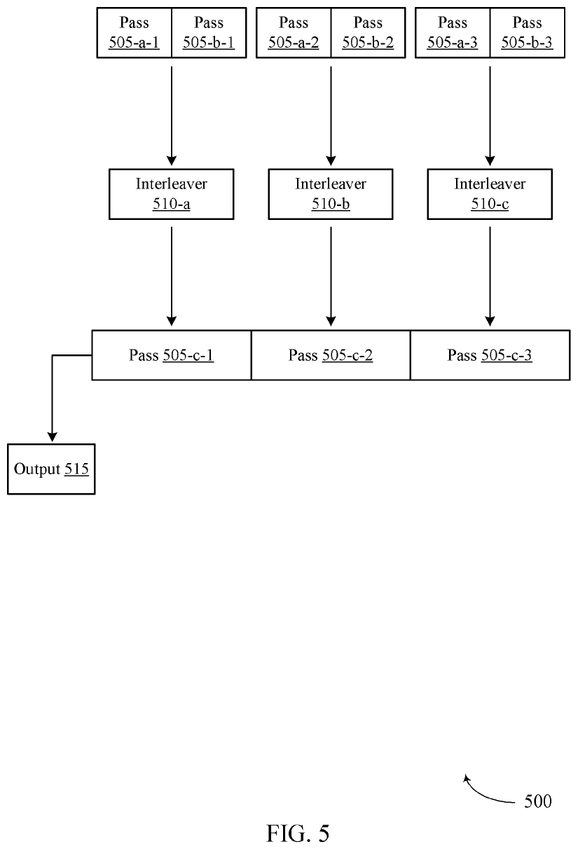

FIG. 5 illustrates an example of a rate matching scheme 500 that supports techniques for iterative decoding using turbo spinal codes in accordance with one or more aspects of the present disclosure. The rate matching scheme 500 may be implemented to realize aspects of the wireless communications system 100 and the wireless communications system 200. For example, a transmitting device 205 may encode a message using a rate matching interleaver of the rate matching scheme 500.

In some implementations, an encoder of a transmitting device 205 may employ the rate matching scheme 500 in the turbo spinal coding scheme 400 described with reference to FIG. 4 to encode and transmit the encoded message to a receiving device 210. Encoders of the transmitting device 205 may employ passes 505-a-1, 505-a-2, and 505-a-3 in a first spinal code of the turbo spinal coding scheme 400, and the encoders of the transmitting device 205 may employ passes 505-b-1, 505-b-2, and 505-b-3 in a second spinal code of the turbo spinal coding scheme 400. After receiving the encoded message, the receiving device 210 may decode the encoded message with iterative decoding techniques.

For instance, in some examples, the encoders of the transmitting device 205 may obtain a first set of code bits (e.g., symbol values x_1,1, x_2,1, and x_3,1) from pass 505-a-1 (pass 1) and obtain a first set of code bits (e.g., symbol values x_1,1′, x_2,1′, and x_3,1′) from pass 505-b-1 (pass A). The encoders of the transmitting device 205 may input the first set of code bits from pass 505-a-1 of the first spinal code and the first set of code bits from pass 505-b-1 of the second spinal code to an interleaver 510-a (the rate matching interleaver). The interleaver 510-a may interleave the first sets of code bits from pass 505-a and pass 505-b-1 to generate code bits for pass 505-c-1 (pass 1A). Additionally, the encoders of the transmitting device 205 may obtain a second set of code bits (e.g., symbol values x_1,2, x_2,2, and x_3,2) from pass 505-a-2 (pass 2) of the first spinal code and a second set of code bits (e.g., symbol values x_1,2′, x_2,2′, and x_3,2′) from pass 505-b-2 (pass B) of the second spinal code. The encoders of the transmitting device 205 may input the second set of code bits from pass 505-a-2 and the second set of code bits from pass 505-b-2 to an interleaver 510-b. The interleaver 510-b may interleave the second sets of code bits from pass 505-a-2 and pass 505-b-2 to generate code bits for pass 505-c-2 (pass 2B). Additionally, the encoders of the transmitting device 205 may obtain a third set of code bits (e.g., symbol values x_1,3, x_2,3, and x_3,3) from pass 505-a-3 (pass 1) of the first spinal code and obtain a third set of code bits (e.g., symbol values x_1,3′, x_2,3′, and x_3,3′) from pass 505-b-3 (pass A) of the second spinal code. The encoders of the transmitting device 205 may input the third set of code bits from pass 505-a-3 and the third set of code bits from pass 505-b-3 to an interleaver 510-c. The interleaver 510-c may interleave the third sets of code bits from pass 505-a-3 and pass 505-b-3 to generate code bits for pass 505-c-3 (pass 3C). The interleavers 510-a, 510-b, and 510-c may be different from the encoder interleaver (e.g., the interleaver 430). Additionally, the interleavers 510-a, 510-b, and 510-c may be the same rate matching interleaver or different rate matching interleavers.

The encoders of the transmitting device 205 may transmit an output 515 that contains an extracted set of bits (e.g., the encoded message) by sequentially obtaining and transmitting the extracted set of bits from the interleaving output buffer, from left to right. For instance, the transmitting device 205 may obtain a first extracted set of bits (redundancy version 1 (RV1)) from the pass 505-c-1, obtain a second extracted set of bits (RV2) from the pass 505-c-2, and obtain a third extracted set of bits (RV3) from the pass 505-c-3. As such, the receiving device 210 may receive RV1, RV2, and RV3 within the output 515 transmitted by the transmitting device 205.

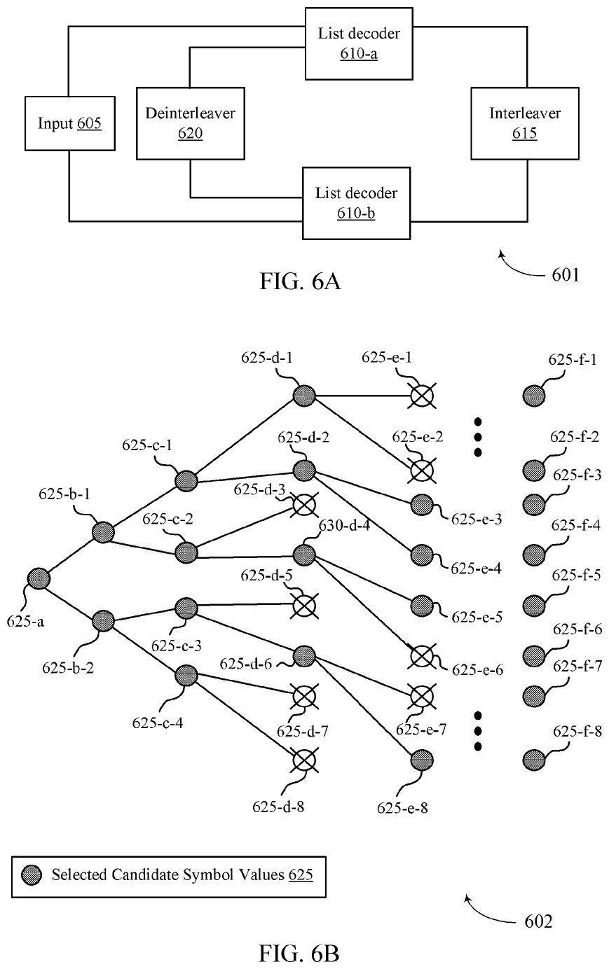

FIG. 6A illustrates an example of a list decoding block diagram 601 that supports techniques for iterative decoding using turbo spinal codes in accordance with one or more aspects of the present disclosure. The list decoding block diagram 601 may be implemented to realize aspects of the wireless communications system 100 or the wireless communications system 200. For example, the list decoding block diagram 601 illustrates a decoding process at a receiving device 210 for decoding signals associated with turbo spinal codes. In some aspects, the list decoding block diagram 601 may illustrate an example implementation of an iterative list decoding technique that the receiving device 210 may use to decode an encoded message.

In some examples, a receiving device 210 may receive a message encoded according to a turbo spinal coding scheme. The message may include a set of bits partitioned into a set of submessages. As illustrated in the list decoding block diagram 601, the receiving device 210 may decode the set of submessages via an input 605, a list decoder 610-a (e.g., a first list decoder), an interleaver 615 (e.g., a first interleaver), a list decoder 610-b (e.g., a second list decoder), and a deinterleaver 620 (e.g., a second interleaver). In some examples, the interleaver 615, the deinterleaver 620, or both, may be row-in column-out rectangular interleaver, a triangular interleaver, a pseudo-random interleaver, or a two-way spinal interleaver. For example, the interleaver 615 and the deinterleaver 620 may be row-in column-out rectangular interleavers, triangular interleavers, pseudo-random interleavers, or two-way spinal interleavers.

The list decoder 610-a may be associated with a first spinal code tree for a first decoding (e.g., forward decoding if a two-way spinal interleaver is used), and the list decoder 610-b may be associated with a second spinal code tree for a second decoding (e.g., backward decoding if a two-way spinal interleaver is used). After receiving the encoded message, the receiving device 210 may perform a first list search operation on the set of submessages to generate a first set of submessage candidates (e.g., estimations of m₁, m₂, m₃, . . . ) using the first spinal code tree. For example, the receiving device 210 may perform QAM demodulation on a signal including the encoded message in order to obtain the encoded bits (e.g., the symbol values generated by RNGs) sent by the transmitter. The encoded bits may be referred to as a received demodulated QAM value, and may serve as the input 605 of the list decoding process. The receiving device 210 may begin the list decoding process by inputting the input 605 to the list decoder 610-a. In accordance with the input 605, the list decoder 610-a may generate a first set of submessage candidates. For instance, the list decoder 610-a may exponentially generate submessage candidates for each node of the first spinal code tree based on an initial input and parameters set for the receiving device 210 until the first set of submessage candidates is generated. As such, for the case of the previous example, the list decoder 610-a may output the first set of submessage candidates for the first decoding.

Additionally, the receiving device 210 may interleave the first set of submessage candidates using the interleaver 615 to generate (e.g., output) a set of interleaved submessage candidates (e.g., estimations of m₁, m₂′, m₃′, . . . ), where the set of interleaved submessage candidates may feed into the list decoder 610-b to generate a second set of submessage candidates on a second spinal code tree. For example, to continue to iterative list decoding process, the receiving device 210 may input the set of interleaved submessage candidates into the list decoder 610-b, and the list decoder 610-b may generate the second set of submessage candidates. The receiving device 210 may decode the encoded message including the encoded submessages based on the first set of submessage candidates from the first spinal code tree and the second set of submessage candidates from the second spinal code tree.

In some examples, the receiving device 210 may remove one or more submessage candidates such that the second set of submessage candidates includes less submessage candidates than the first set of submessage candidates. For instance, the receiving device 210 may refrain from including one or more submessage candidates in the second set of submessage candidates if the one or more submessage candidates fail to satisfy a path metric. The path metric may convey a path cost that indicates a quality of decoding for a potential path within a spinal code tree, where the potential path includes a subset of submessage candidates of the set of submessage candidates. Accordingly, the receiving device 210 may determine that a potential path of the second spinal code tree fails to meet the path metric, and the receiving device 210 may eliminate, from the second set of submessage candidates, one or more submessage candidates of the potential path failing to meet the path metric. In some examples, the receiving device 210 may eliminate the one or more submessage candidates by keeping a threshold quantity of submessage candidates in the second set of submessage candidates. For instance, a maximum list size Lₘₐₓ may be configured for the iterative list decoding process, and the receiving device 210 may keep at most Lₘₐₓ submessage candidates.

In some examples, the receiving device 210 may attempt to decode the encoded message based on the first set of submessage candidates and the second set of submessage candidates. If the receiving device 210 fails to decode the message in a current iteration of the iterative decoding process 220, the receiving device 210 may perform a next iteration of iterative list decoding process. For example, the receiving device 210 may not have the capability to decode the message received from the transmitting device based on the first set of submessage candidates and the second set of submessage candidates. To have a greater chance to successfully decode the encoded message, the receiving device 210 may further reduce the submessage candidates in the next iteration of the iterative list decoding process. For example, the receiving device 210 may input the second set of submessage candidates to the deinterleaver 620 to generate an input for the list decoder 610-a in the next iteration of the iterative decoding list decoding process. In some examples, a maximum iteration Iₘₐₓ may be configured for the iterative list decoding process, and the receiving device 210 may be capable of performing a next iteration of the iterative list decoding process until reaching the Iₘₐₓ iteration, such that the Iₘₐₓ iteration serves as a threshold quantity of iterations.

In some examples, the receiving device 210 may determine a quantity of submessage candidates remaining after attempting to decode the message in order to determine whether to terminate the iterative list decoding process. For instance, whether or not the receiving device 210 successfully decodes the encoded message based on the first set of submessage candidates and the second set of submessage candidates, the receiving device 210 may determine a quantity of submessage candidates left over in the current iteration of the iterative list decoding process. If the receiving device 210 determines that the quantity of submessage candidates remaining after attempting to decode the message is equal to one, then the receiving device 210 may terminate the iterative list decoding process.

Additionally, or alternatively, the receiving device 210 may terminate the iterative list decoding process based on performing a CRC. The receiving device 210 may perform a CRC based on a message candidate corresponding to a first submessage candidate of the first set of submessage candidates and a second submessage candidate of the second set of submessage candidates. For instance, in a last iteration (e.g., Iₘₐₓ) of the iterative list decoding process, the receiving device 210 may perform the CRC to select a message candidate, where the message candidate includes a submessage candidate of each of the first set of submessage candidates and the second set of submessage candidates. After selecting the submessage candidate of each set, the receiving device 210 may perform a pass or fail operation on bits of a decoding hypothesis to determine if the message may be correctly decoded with the selected message candidate. If the receiving device 210 determines that the message is decoded incorrectly, the receiving device 210 may deem the CRC to be unsuccessful. Alternatively, if the receiving device 210 determines that the message is decoded correctly, the receiving device 210 may deem the CRC to be successful. In some examples, the receiving device 210 may terminate the iterative list decoding process based on performing the CRC. Additionally, or alternatively, the receiving device 210 may terminate the iterative list decoding process based on performing a successful CRC.

FIG. 6B shows an example list decoding scheme 602 that supports techniques for iterative decoding using turbo spinal codes in accordance with one or more aspects of the present disclosure. The list decoding scheme 602 may be implemented to realize aspects of the wireless communications system 100 or the wireless communications system 200. For example, the list decoding scheme 602 may illustrate an example implementation of an iterative list decoding technique that the receiving device 210 may use to eliminate submessage candidates through multiple iterations of an iterative list decoding process.

In some implementations, a receiving device 210 may receive a message encoded according to a turbo spinal coding scheme and may employ a cost function associated with a Euclidean distance between a channel measurement associated with the signal and each of a set of candidate symbol values 625 multiplied by the channel (or an estimated channel). In other words, the cost function may be associated with a Euclidean distance between a received signal and a product of each of the candidate symbol values 625 and the channel (or the estimated channel). In some implementations, the list decoding scheme 602 may be implemented to evaluate candidates of a search space, such as evaluating a PDCCH search space for control information intended for a receiving device 210 or set of receiving device 210s.

In some aspects, a spinal code tree, which may also be referred to as a maximum likelihood (ML) decoder herein, may generate a set of (such as all) codewords out of a size n bits (such that a total quantity of codewords is 2ⁿ) and may calculate a distance between generated symbol values at the receiver device and actually received (noisy) symbol values per codeword. In such aspects, the decoder may infer, ascertain, or otherwise determine that the decoded message is the one with a minimal distance over all received symbol values or spines.

In some implementations of the present disclosure, a receiving device 210 may employ a list decoder that is able to achieve lower computational complexity and leverage aspects associated with rateless coding (such as spinal coding). For example, because a spinal encoder may apply a hash function sequentially or cumulatively across multiple submessages, input messages with a common prefix also may have a common spine value (such as a common spine prefix or a common value of a spine conveying information associated with the common prefix), whereas symbol values produced or output by an RNG from the common spine values may be the same or different. As such, a receiving device 210 may use this structure to decompose a total distance into a summation over multiple spines. Accordingly, a receiving device 210 may calculate a summation for a set of (such as all) transmissions or candidates that share a same spine value s_i (such as s_0). Thus, in some implementations, a receiving device 210 may implement a decoding process such as a tree decoding with a root at spine s_0. The receiving device 210 may sum or accumulate branch costs on a path from the root to a node and calculate a path cost (which may be referred to as a path metric or a decoding metric) of the node.

In accordance with a cost function, and supposing, as an example, a message M* and some other message M′ that differs in an i^{th} bit, spines including and after a spine index of ceil

$$( \frac{i}{k} )$$

may be dissimilar (and all other symbols before a spine index of ceil

$$( \frac{i}{k} )$$

may be the same across the two transmissions) such that the difference between the two decoded transmissions is present in the last O(log n) bits. As such, the earlier the error in M′, the larger the path cost may be. If a receiving device 210 constructs an entire ML decoding tree and computes path costs for each of the nodes (which may be referred to as leaves), the receiving device 210 may select B nodes (such as the B nodes or leaves having the lowest path cost) and may trace back through the decoding tree to find that each of the B selected nodes converge to a relatively small quantity of common “ancestors,” where an “ancestor” may refer to a node of a decoding tree relatively closer to a root of the tree than the B selected nodes and where a common “ancestor” may refer to a node from which each of the B selected nodes can be traced back to.

Thus, a receiving device 210 may implement a bubble decoder associated with a depth parameter d and a beam width parameter B and, instead of searching an entire decoding tree, the receiving device 210 may maintain B common ancestors (beams) and a partial decoding tree rooted at each ancestor of depth d. In some implementations, the receiving device 210 may select a node with a lowest path cost and may return a complete message corresponding to the selected node (such as a complete message conveyed by a spine associated with the selected node of the decoding tree). Additionally, or alternatively, the receiving device 210 may perform a CRC on a set of (such as all) left codewords, which may include a total of B2^{kd} remaining codewords.

A width of the decoding tree may be associated with or given by the parameter k (such that the tree may expand by 2^{k} nodes or leaves at each stage). As such, the width of the decoding tree may decrease as k decreases and the decoding tree may correspondingly include more decoding stages (as a result of n/k increasing) as k decreases. Further, as the width of the decoding tree decreases and as a quantity of decoding stages increases, a latency until a next transmission (such as a next retransmission) may increase as well. Likewise, the width of the decoding tree may increase as k increases and the decoding tree may correspondingly include fewer decoding stages (as a result of n/k decreasing) as k increases. Further, as the width of the decoding tree increases and as a quantity of decoding stages decreases, a latency until a next transmission (such as a next retransmission) may decrease as well.

Accordingly, and as shown in the list decoding scheme 500, a receiving device 210 may generate or otherwise use a decoding tree of n/k decoding stages or levels and 2ⁿ leaves or nodes at a last or final decoding stage. A root of the decoding tree may be s₀ (or s_0) and may branch out to 2^{k} leaves at a first decoding stage associated with a spine s₁ (or s_1). Each leaf of the first decoding stage associated with the spine s_1 may branch out to 2^{k} leaves at a next decoding stage associated with a next spine, and eventually to a decoding stage associated with a spine s_{L} (or s_L). The decoding tree may end at a final decoding stage associated with a spine

$${s}_{\frac{n}{k}} ( or s \_ \frac{n}{k} ) .$$

In some implementations, a receiving device 210 may recognize that decoding hypotheses, which may be equivalently referred to as candidate symbol values 625, that have same initial states that share same symbol hypotheses or guesses (such as decoding hypotheses for nodes or leaves that have a common “ancestor” node in the decoding tree) are identical in a decoding stage associated with the same initial states that share the same symbol hypotheses or guesses. In other words, decoding stages up to the common “ancestor” node in the decoding tree may be the same for decoding hypotheses of later decoding stages that share the same symbol hypotheses or guesses for that common “ancestor” node. As such, the receiving device 210 may merge such initial identical states (and thus save some decoding complexity and computational cost).

Each of the leaves or nodes at each decoding stage of the decoding tree may correspond to decoding hypotheses or candidate symbol values 625 associated with an encoded message at a receiving device 210. As part of the list decoding scheme 602, for example, a receiving device 210 may generate a set of candidate symbol values 625 at each decoding stage corresponding to a spine and may select one or more candidate symbol values 625 at each decoding stage or for each spine. For example, a receiving device 210 may evaluate a set of candidate symbol values 625 in accordance with a cost function associated with a distance (such as a Euclidean distance) between each of the set of candidate symbol values 625 and an actually received or measured symbol value and may select the one or more candidate symbol values 625 associated with the smallest cost functions (or the shortest Euclidean distances).

For example, the receiving device 210 may initialize or begin a decoding tree assuming a candidate symbol value 625-a associated with an s_0 value, which may be associated with a spine s_1. In some aspects, s_0 may be the received demodulated QAM value associated with bits of the encoded message.

The receiving device 210 may generate a set of candidate symbol values 625-b for a subsequent spine 320 s_2, including a candidate symbol value 625 b-1 and a candidate symbol value 625 b-2. In some implementations, the receiving device 210 may generate the set of candidate symbol values 625-b by inputting, into a first hash function, the s_0 value and multiple first sets of k candidate bits (which may function as or be examples of possibilities for bits included in a first submessage, such as possible bit string values of a submessage 310-a as shown in FIG. 3) and obtaining, as an output of the first hash function, a first set of candidate encoded values. The receiving device 210 may input, into a first RNG, the first set of candidate encoded values (such as the first set of candidate spines) and obtain, as an output of the first RNG, the set of candidate symbol values 625-b for the spine.

The receiving device 210 may input, into a second RNG, the second set of candidate encoded values (such as the second set of candidate spines) and obtain, as an output of the second RNG, the set of candidate symbol values 625-c. As such, the receiving device 210 may generate a set of candidate symbol values 625-c for a subsequent spine. In some implementations, the receiving device 210 may generate the set of candidate symbol values 625-c-1 and 530-c-2 by inputting, into a second hash function, a candidate spine value associated with the candidate symbol value 625-b-1 and multiple second sets of k candidate bits (which may function as or be examples of possibilities for bits included in a second submessage, such as possible bit string values of a submessage 310-b as shown in FIG. 3) for the subsequent spine. Additionally, the receiving device 210 may generate the set of candidate symbol values 625-c-3 and 530-c-4 by inputting, into the second hash function, a candidate spine value associated with the candidate symbol value 625-b-2 and multiple second sets of k candidate bits for the subsequent spine

The receiving device 210 may generate a set of candidate symbol values 625-d for a subsequent spine 320, including candidate symbol values 625-d-1, 625-d-2, 625-d-3, 625-d-4, 625-d-5, 625-d-6, 625-d-7, and 625-d-8. In some implementations, the receiving device 210 may generate the set of candidate symbol values 625-d by inputting, into a third hash function, a spine value associated with the candidate symbol values 625-c and multiple third sets of k candidate bits (which may function as or be examples of possibilities for bits included in a third submessage, such as possible bit string values of a submessage 310-c as shown in FIG. 3) and obtaining, as an output of the third hash function, a third set of candidate encoded values (such as a third set of candidate spines for a subsequent spine). The receiving device 210 may input, into a third RNG, the candidate encoded values 625-c and obtain, as an output of the third RNG, the set of candidate symbol values 625-d.

The receiving device 210 may compare each of the set of candidate symbol values 625-d to a channel measurement (of a modulation symbol for that subsequent spine, if transmitted) and may select B candidate symbol values 625-d that are associated with a smallest cost function or Euclidean distance relative to the channel measurement. As shown in the list decoding scheme 602, B=4 (such that the receiving device 210 may select four candidate symbol values 625 for further consideration or evaluation). For instance, the receiving device 210 may select the candidate symbol values 625-d-1, 625-d-2, 625-d-4, and 625-d-6, potentially among other candidate symbol values 625-d associated with potential spine values for the subsequent spine.

Until terminating the list decoding scheme 602, the receiving device 210 may generate a set of candidate symbol values 625-e for a subsequent spine, including candidate symbol values 625-e-1, 625-e-2, 625-e-3, 625-e-4, 625-e-5, 625-e-6, 625-e-7, and 625-e-8. In some implementations, the receiving device 210 may generate the set of candidate symbol values 625-e by inputting, into a fourth hash function, a spine value associated with the candidate symbol values 625-d-1, 625-d-2, 625-d-4, 625-d-6 and multiple fourth sets of k candidate bits and obtaining, as an output of the fourth hash function, a fourth set of candidate encoded values (such as a fourth set of candidate spines for a subsequent spine). The receiving device 210 may input, into a fourth RNG, the third set of candidate encoded values and obtain, as an output of the fourth RNG, the set of candidate symbol values 625-e. The receiving device 210 may compare each of the set of candidate symbol values 625-e to a channel measurement (of a modulation symbol for that spine 320, if transmitted) and may select B candidate symbol values 625-e that are associated with a smallest cost function or Euclidean distance relative to the channel measurement.

The receiving device 210 may likewise generate other sets of candidate symbol values until the receiving device 210 reaches an

$$\frac{{n}^{th}}{k}$$

decoding stage associated with a subsequent spine, where the receiving device 210 may generate a set of candidate symbol values 625-f including a candidate symbol value 625-f-1, 625-f-2, 625-f-3, 625-f-4, 625-f-5, 625-f-6, 625-f-7, and 625-f-8. In some aspects, the

$$\frac{{n}^{th}}{k}$$

decoding stage may be a final decoding stage associated with a final spine (such that the spine conveys information associated with the entire message). In such aspects, the receiving device 210 may measure, detect, or otherwise identify which of the candidate symbol values 625 is closest to the channel measurement and may infer that whichever candidate symbol value 625 is closest is associated with a correct decoding of the message.

In some implementations, a decoder of a receiving device 210 may calculate a Euclidean distance metric at each step or stage of the list decoding scheme 500. For example, the decoder may implement an encoder block on each possible codeword with a length of n and, on each stage of the list decoding scheme 602, may calculate a path metric between a set of candidate symbol values 625 relative to a constellation symbol or point. A receiving device 210 may store or otherwise save the metric throughout (all of) the stages of the list decoding scheme 602 (such as across a quantity of passes or transmission occasions associated with a given message) and may identify, notice, or otherwise determine that if a hash function received two inputs that differ (even by one bit), an output of the hash function may be different as a result of the properties of the hash functions. Thus, the calculated metric, which may be an example of a decoding metric, a path cost metric, or a value of the cost function, may be different as well. A receiving device 210 may calculate and save the path cost metric and the path cost metric may increase from a first (such as earliest) symbol, spine, or coding index at which the decoder of the receiving device 210 begins to diverge from an actually received or measured constellation symbol or point.

In accordance with examples as disclosed herein, characteristics of the list decoding scheme to improve various implementations of iterative list decoding for turbo spinal codes such that the receiving device 210 may decode an encoded message with reduced overhead. For example, the receiving device 210 may select a path associated with a minimal path cost to attempt to decode the message. If the receiving device 210 fails to decode the message in a current iteration of the iterative list decoding process using a first set of submessage candidates and a second set of submessage candidates, the receiving device 210 may perform a next iteration of the iterative list decoding process. Accordingly, the receiving device 210 may continue the iterative list decoding process until the receiving device 210 reaches a maximum iteration Iₘₐₓ configured for the iterative list decoding process or until one submessage candidate remains, after which the receiving device 210 may terminate the iterative list decoding process.

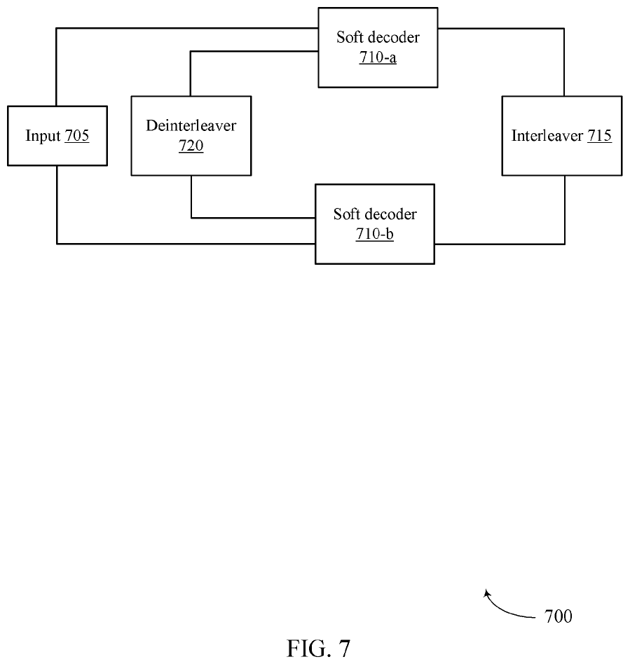

FIG. 7 illustrates an example of a soft decoding block diagram 700 that supports techniques for iterative decoding using turbo spinal codes in accordance with one or more aspects of the present disclosure. The soft decoding block diagram 700 may be implemented to realize aspects of the wireless communications system 100 or the wireless communications system 200. For example, the soft decoding block diagram 700 illustrates a decoding process at a receiving device 210 for decoding signals associated with turbo spinal codes. In some aspects, the soft decoding block diagram 700 may illustrate an example implementation of an iterative soft decoding technique that the receiving device 210 may use to decode an encoded message.

In some implementations, the receiving device 210 may perform the iterative soft decoding process using a soft decoding algorithm. For example, the receiving device 210 may use a soft decoder 710-a and a soft decoder 710-b in the iterative soft decoding process. The soft decoder 710-a may be associated with a first decoding, and the soft decoder 710-b may be associated with a second decoding. The receiving device 210 may begin the soft iterative decoding process by inputting an initial input 705 (e.g., a first estimation of a first submessage) to the soft decoder 710-a. In accordance with the initial input, the soft decoder 710-a may output the first set of soft information. In some examples, the receiving device 210 may determine a first LLR based on the first set of soft information, where the first LLR indicates a goodness of fit for the first estimation of the submessage.

Additionally, the receiving device 210 may interleave the first set of soft information using the interleaver 715 to generate a set of interleaved soft information. For instance, for the case of the previous example, the soft decoder 710-a may input the first set of soft information to the interleaver 715, and the interleaver 715 may output the set of interleaved soft information. In some examples, the receiving device 210 may perform a second soft decoding operation on the set of interleaved soft information to generate a second set of soft information, where the second set of soft information indicates a probability that a second estimation of the submessage is correctly estimated by the receiving device 210. For instance, when performing the second soft decoding operation, the receiving device 210 may input the set of interleaved soft information to the soft decoder 710-b, and the soft decoder 710-b may generate the second set of soft information for a second estimation of the submessage. In some examples, the receiving device 210 may determine a second LLR based on the second set of soft information. In some cases, the second set of soft information may be different from or the same as the first set of soft information. Additionally, or alternatively, the second LLR may be different from or the same as the first LLR. In some examples, the second estimation of the submessage may be more correct than the first estimation of the submessage if the second LLR is greater than the first LLR.

The receiving device 210 may decode the message 215 (including the encoded submessages) based on the first set of soft information (for the first decoding) and the second set of soft information (for the second decoding). Additionally, or alternatively, the receiving device 210 may decode the message 215 based on the first LLR and the second LLR. For example, if the second LLR is greater than the second LLR, the receiving device 210 may decode the message 215 such that the decoded submessage of the message 215 is more similar to the second estimation of the submessage than the first estimation of the submessage.

In some examples, the receiving device 210 may perform a second iteration of the first soft decoding operation. For example, the receiving device 210 may input the second set of soft information to the deinterleaver 720 to generate an input for a second iteration of the first soft decoding operation and continue the iterative decoding process. In some examples, a maximum iteration Iₘₐₓ may be configured for the iterative soft decoding process, and the receiving device 210 may be capable of performing a next iteration of the iterative soft decoding process until reaching the Iₘₐₓ iteration, such that the Iₘₐₓ iteration serves as a threshold quantity of iterations.

The receiving device 210 may continue the iterative soft decoding process until a CRC is successful. For instance, in the last iteration (e.g., Iₘₐₓ) of the iterative soft decoding process, the receiving device 210 may perform a CRC based on the first set of soft information and the second set of soft information generated in the last iteration. The receiving device 210 may terminate the iterative soft decoding process based on the success of the CRC (indicating the correctness for decoding the message 215 satisfies a threshold).

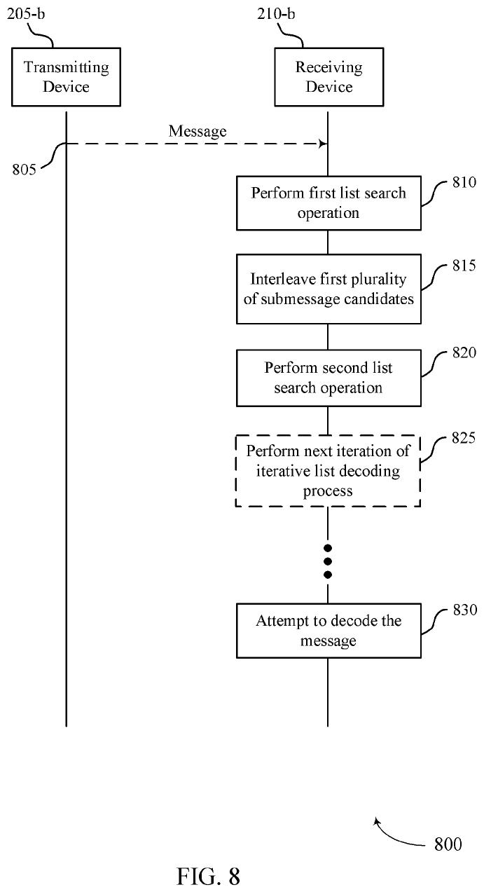

FIG. 8 illustrates an example of a process flow 800 that supports techniques for iterative decoding using turbo spinal codes in accordance with one or more aspects of the present disclosure. The process flow 800 may implement or be implemented by aspects of wireless communications systems 100 or 200. For example, the process flow 800 may illustrate operations between a transmitting device 205-b and a receiving device 210-b, which each may be an example of a UE 115 or a network entity 105, as described with reference to FIG. 1 and FIG. 2. In the following description of the process flow 800, the operations between the transmitting device 205-b and the receiving device 210-b may be transmitted in a different order than the example order shown, or the operations performed by the transmitting device 205-b and the receiving device 210-b may be performed in different orders or at different times. Some operations may also be omitted from the process flow 800, and other operations may be added to the process flow 800.

At 805, the transmitting device 205-b may transmit, and the receiving device 210-b may receive, a message (e.g., an encoded message) including a set of bits partitioned into a set of submessages. In some examples, the transmitting device 205-b may use a turbo spinal code in an encoding process to encode the message via a first encoding in a first spinal code of the turbo spinal code and via a second encoding in a second spinal code of the turbo spinal code. In such examples, the transmitting device 205-b may partition the message into a set of submessages and input the set of submessages into an interleaver (e.g., a row-in column-out rectangular interleaver, a triangular interleaver, a pseudo-random interleaver, or a two-way spinal interleaver), and the interleaver may output an interleaved set of submessages. The transmitting device 205-b may input the set of submessages into the first spinal code for the first encoding and input the interleaved set of submessages into the second spinal code for the second encoding such that the transmitting device 205-b may generate rateless outputs for an encoded message. Accordingly, the receiving device 210-b may receive the encoded message.

At 810, the receiving device 210-b may perform a first list search operation associated with a first spinal code tree of an iterative list decoding process to generate a first set of submessage candidates. The first spinal code tree may be associated with a first encoding. In some examples, the first set of submessage candidates may be based on a threshold quantity of submessage candidates.

At 815, the receiving device 210-b may interleave the first set of submessage candidates to generate a set of interleaved submessage candidates. For example, the receiving device 210-b may input the first set of submessage candidates to an interleaver (e.g., a row-in column-out rectangular interleaver, a triangular interleaver, a pseudo-random interleaver, or a two-way spinal interleaver), and the interleaver may output a set of interleaved submessage candidates. In some examples, the interleaver used by the receiving device 210-b in the iterative list decoding process may be similar to or different from the interleaver used by the transmitting device 205-b in the encoding process for the transmitted message.

At 820, the receiving device 210-b may perform a second list search operation associated with a second spinal code tree of the iterative list decoding process using the set of interleaved submessage candidates to generate a second set of submessage candidates. The second spinal code tree may be associated with a second encoding. In some examples, the second set of submessage candidates may be based on a threshold quantity of submessage candidates. The threshold quantity of submessage candidates for the second set of submessage candidates may be the same or different from that of the first set of submessage candidates.

In some examples, the receiving device 210-b may reduce the quantity of submessage candidates included in the second set of submessage candidates during an iteration of the iterative list decoding process. For instance, in some cases, the receiving device 210-b may determine that one or more submessage candidates fail to satisfy a path metric based on performing the second list search operation on the second spinal code tree. In such cases, the receiving device 210-b may refrain from including the one or more submessage candidates in the second set of submessage candidates based on the determining.

At 825, the receiving device 210-b may optionally perform a next iteration of the iterative list decoding process. In some examples, the receiving device 210-b may perform the next iteration based on identifying that more than one submessage candidate remains after performing the second list search operation. For instance, in some cases, the receiving device 210-b may identify that at least two submessage candidates of the second set of submessage candidates are remaining based on performing the second list search operation on the second spinal code tree. In such cases, the receiving device 210-b may perform a next iteration of the iterative list decoding process based on identifying that the at least two submessage candidates of the second set of submessage candidates are remaining. In some other cases, the receiving device 210-b may identify that one submessage candidate of the second set of submessage candidates remains. In such other cases, the receiving device 210-b may refrain from performing the next iteration of the iterative list decoding process.

In some examples, the next iteration may be based on a failure of a current iteration to meet a maximum iteration threshold of the iterative list decoding process. For example, if the maximum iteration threshold for the iterative list decoding process is configured to be 15, and the current iteration is 9, the receiving device 210-b may perform another iteration because the maximum iteration threshold has not been met.

In some examples, the receiving device 210-b may deinterleave the second set of submessage candidates from the second spinal code tree in order to perform the next iteration of the iterative list decoding process. For instance, the receiving device 210-b may deinterleave the second set of submessage candidates to generate an input for the first list search operation associated with the first spinal code tree in the next iteration of the iterative list decoding process. In some examples, the receiving device 210-b may input the second set of submessage candidates to a deinterleaver, which may also be referred to as a second interleaver (e.g., a row-in column-out rectangular interleaver, a triangular interleaver, a pseudo-random interleaver, or a two-way spinal interleaver). The deinterleaver may be similar to or different from the interleaver used by the receiving device 210-b in the iterative list decoding process.

At 830, the receiving device 210-b may attempt to decode the message based on the first set of submessage candidates and the second set of submessage candidates. In some examples, the receiving device 210-b may attempt to decode the message by performing a CRC on the last iteration of the iterative list decoding process. For instance, if the current iteration of the iterative list decoding process is equivalent to the maximum iteration threshold value, the receiving device 210-b may perform a CRC. In some cases, the receiving device 210-b may perform a CRC based on a message candidate corresponding to a first submessage candidate of the first set of submessage candidates and a second submessage candidate of the second set of submessage candidates. The receiving device 210-b may terminate the iterative list decoding process based on the success of the CRC.

In some examples, the receiving device 210-b may terminate the iterative list decoding process based on the quantity of submessage candidates remaining after attempting to decode the message. For instance, the receiving device 210-b may determine a quantity of submessage candidates remaining after the attempting to decode the message, and the receiving device 210-b may terminate the iterative list decoding process based on determining that the quantity of submessage candidates remaining after the attempting to decode the message is equal to one.

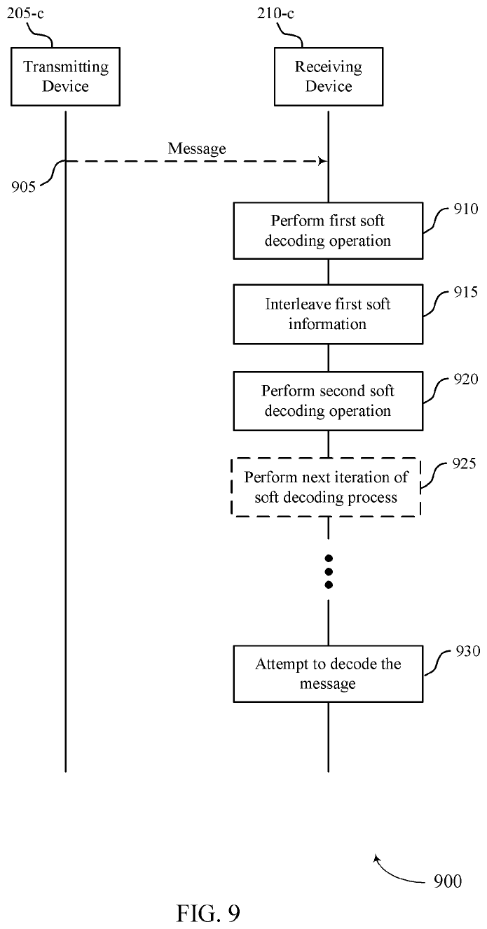

FIG. 9 illustrates an example of a process flow 900 that supports techniques for iterative decoding using turbo spinal codes in accordance with one or more aspects of the present disclosure. The process flow 900 may implement or be implemented by aspects of wireless communications systems 100 or 200. For example, the process flow 900 may illustrate operations between a transmitting device 205-c and a receiving device 210-c, which each may be an example of a UE 115 or a network entity 105, as described with reference to FIG. 1 and FIG. 2. In the following description of the process flow 900, the operations between the transmitting device 205-c and the receiving device 210-c may be transmitted in a different order than the example order shown, or the operations performed by the transmitting device 205-c and the receiving device 210-c may be performed in different orders or at different times. Some operations may also be omitted from the process flow 900, and other operations may be added to the process flow 900.

At 905, the transmitting device 205-c may transmit, and the receiving device 210-c may receive, a message (e.g., an encoded message) including a set of bits partitioned into a set of submessages. In some examples, the transmitting device 205-c may use a turbo spinal code in an encoding process to encode the message via a first encoding in a first spinal code of the turbo spinal code and via a second encoding in a second spinal code of the turbo spinal code. In such examples, the transmitting device 205-c may partition the message into a set of submessages and input the set of submessages into an interleaver (e.g., a row-in column-out rectangular interleaver, a triangular interleaver, a pseudo-random interleaver, or a two-way spinal interleaver), and the interleaver may output an interleaved set of submessages. The transmitting device 205-c may input the set of submessages into the first spinal code for the first encoding and input the interleaved set of submessages into the second spinal code for the second encoding such that the transmitting device 205-c may generate rateless outputs for an encoded message. Accordingly, the receiving device 210-c may receive the encoded message.

At 910, the receiving device 210-c may perform a first soft decoding operation associated with a first spinal code of an iterative soft decoding process to generate a first set of soft information. The first spinal code may be associated with a first encoding. In some examples, the receiving device 210-c may determine a first LLR based on the first set of soft information. In such examples, the first LLR may indicate a goodness of fit for a first estimation of a submessage of the message, where the first estimation may be generated by the receiving device 210-c in accordance with the first set of soft information.

At 915, the receiving device 210-c may interleave the first set of soft information using an interleaver to generate a set of interleaved soft information. For example, the receiving device 210-c may input the first set of soft information to an interleaver (e.g., a row-in column-out rectangular interleaver, a triangular interleaver, a pseudo-random interleaver, or a two-way spinal interleaver), and the interleaver may output a set of interleaved soft information. In some examples, the interleaver used by the receiving device 210-c in the iterative soft decoding process may be similar to or different from the interleaver used by the transmitting device 205-c in the encoding process for the transmitted message.

At 920, the receiving device 210-c may perform a second soft decoding operation associated with a second spinal code of the iterative soft decoding process using the set of interleaved soft information to generate a second set of soft information. The second spinal code may be associated with a second encoding. In some examples, the receiving device 210-c may determine a second LLR based on the second set of soft information. In such examples, the second LLR may indicate a goodness of fit for a second estimation of the submessage of the message, where the second estimation may be generated by the receiving device 210-c in accordance with the second set of soft information.

At 925, the receiving device 210-c may perform a next iteration of the iterative soft decoding process. In some examples, the next iteration may be based on a failure of a current iteration to meet a maximum iteration threshold of the iterative soft decoding process. For example, if the maximum iteration threshold for the iterative soft decoding process is configured to be 15, and the current iteration is 9, the receiving device 210-c may perform another iteration because the maximum iteration threshold has not been met.

In some examples, the receiving device 210-c may deinterleave the second set of soft information from the second spinal code in order to perform the next iteration of the iterative soft decoding process. For instance, the receiving device 210-c may deinterleave the second set of soft information to generate an input for the first soft decoding operation associated with the first spinal code in the next iteration of the iterative soft decoding process. In some examples, the receiving device 210-c may input the second set of soft information to a deinterleaver, which may also be referred to as a second interleaver (e.g., a row-in column-out rectangular interleaver, a triangular interleaver, a pseudo-random interleaver, or a two-way spinal interleaver). The deinterleaver may be similar to or different from the interleaver used by the receiving device 210-c to generate the set of interleaved soft information from the first set of soft information.

At 930, the receiving device 210-c may attempt to decode the message based on the first set of soft information and the second set of soft information. In some examples, the receiving device 210-c may attempt to decode the message by performing a CRC on the last iteration of the iterative soft decoding process. For instance, if the current iteration of the iterative soft decoding process is equivalent to the maximum iteration threshold value, the receiving device 210-c may perform a CRC. In some cases, the receiving device 210-c may perform a CRC based on a message candidate corresponding to a first submessage candidate of the first set of submessage candidates and a second submessage candidate of the second set of submessage candidates. The receiving device 210-c may terminate the iterative soft decoding process based on the success of the CRC. Additionally, or alternatively, the receiving device 210-c may terminate the iterative soft decoding process based on the first LLR, the second LLR, or both.

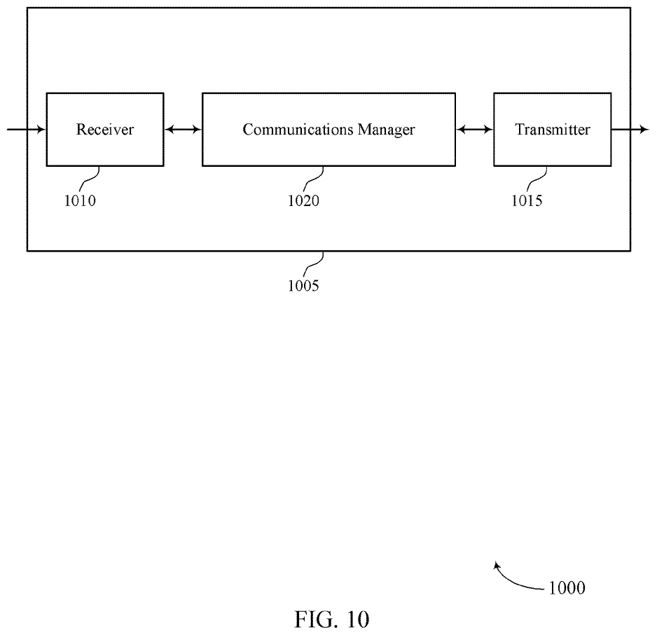

FIG. 10 shows a block diagram 1000 of a device 1005 that supports techniques for iterative decoding using turbo spinal codes in accordance with one or more aspects of the present disclosure. The device 1005 may be an example of aspects of a UE 115 or a network entity 105 as described herein. The device 1005 may include a receiver 1010, a transmitter 1015, and a communications manager 1020. The device 1005 may also include a processor. Each of these components may be in communication with one another (e.g., via one or more buses).

The receiver 1010 may provide a means for receiving information such as packets, user data, control information, or any combination thereof associated with various information channels (e.g., control channels, data channels, information channels related to techniques for iterative decoding using turbo spinal codes). Information may be passed on to other components of the device 1005. The receiver 1010 may utilize a single antenna or a set of multiple antennas.

The transmitter 1015 may provide a means for transmitting signals generated by other components of the device 1005. For example, the transmitter 1015 may transmit information such as packets, user data, control information, or any combination thereof associated with various information channels (e.g., control channels, data channels, information channels related to techniques for iterative decoding using turbo spinal codes). In some examples, the transmitter 1015 may be co-located with a receiver 1010 in a transceiver module. The transmitter 1015 may utilize a single antenna or a set of multiple antennas.

The communications manager 1020, the receiver 1010, the transmitter 1015, or various combinations thereof or various components thereof may be examples of means for performing various aspects of techniques for iterative decoding using turbo spinal codes as described herein. For example, the communications manager 1020, the receiver 1010, the transmitter 1015, or various combinations or components thereof may support a method for performing one or more of the functions described herein.

In some examples, the communications manager 1020, the receiver 1010, the transmitter 1015, or various combinations or components thereof may be implemented in hardware (e.g., in communications management circuitry). The hardware may include a processor, a digital signal processor (DSP), a central processing unit (CPU), an application-specific integrated circuit (ASIC), a field-programmable gate array (FPGA) or other programmable logic device, a microcontroller, discrete gate or transistor logic, discrete hardware components, or any combination thereof configured as or otherwise supporting a means for performing the functions described in the present disclosure. In some examples, a processor and memory coupled with the processor may be configured to perform one or more of the functions described herein (e.g., by executing, by the processor, instructions stored in the memory).

Additionally, or alternatively, in some examples, the communications manager 1020, the receiver 1010, the transmitter 1015, or various combinations or components thereof may be implemented in code (e.g., as communications management software or firmware) executed by a processor. If implemented in code executed by a processor, the functions of the communications manager 1020, the receiver 1010, the transmitter 1015, or various combinations or components thereof may be performed by a general-purpose processor, a DSP, a CPU, an ASIC, an FPGA, a microcontroller, or any combination of these or other programmable logic devices (e.g., configured as or otherwise supporting a means for performing the functions described in the present disclosure).

In some examples, the communications manager 1020 may be configured to perform various operations (e.g., receiving, obtaining, monitoring, outputting, transmitting) using or otherwise in cooperation with the receiver 1010, the transmitter 1015, or both. For example, the communications manager 1020 may receive information from the receiver 1010, send information to the transmitter 1015, or be integrated in combination with the receiver 1010, the transmitter 1015, or both to obtain information, output information, or perform various other operations as described herein.

The communications manager 1020 may support wireless communication at a wireless device in accordance with examples as disclosed herein. For example, the communications manager 1020 may be configured as or otherwise support a means for receiving a message including a set of multiple bits partitioned into a set of multiple submessages. The communications manager 1020 may be configured as or otherwise support a means for performing a first list search operation associated with a first spinal code tree of an iterative list decoding process to generate a first set of multiple submessage candidates. The communications manager 1020 may be configured as or otherwise support a means for interleaving the first set of multiple submessage candidates to generate a set of interleaved submessage candidates. The communications manager 1020 may be configured as or otherwise support a means for performing a second list search operation associated with a second spinal code tree of the iterative list decoding process using the set of interleaved submessage candidates to generate a second set of multiple submessage candidates. The communications manager 1020 may be configured as or otherwise support a means for attempting to decode the message based on the first set of multiple submessage candidates and the second set of multiple submessage candidates.

Additionally, or alternatively, the communications manager 1020 may support wireless communication at a wireless device in accordance with examples as disclosed herein. For example, the communications manager 1020 may be configured as or otherwise support a means for receiving a message including of a first set of multiple bits partitioned into a set of multiple submessages. The communications manager 1020 may be configured as or otherwise support a means for performing a first soft decoding operation associated with a first spinal code of an iterative soft decoding process to generate a first set of soft information. The communications manager 1020 may be configured as or otherwise support a means for interleaving the first set of soft information using an interleaver to generate a set of interleaved soft information. The communications manager 1020 may be configured as or otherwise support a means for performing a second soft decoding operation associated with a second spinal code of the iterative soft decoding process using the set of interleaved soft information to generate a second set of soft information. The communications manager 1020 may be configured as or otherwise support a means for attempting to decode the message based on the first set of soft information and the second set of soft information.

By including or configuring the communications manager 1020 in accordance with examples as described herein, the device 1005 (e.g., a processor controlling or otherwise coupled with the receiver 1010, the transmitter 1015, the communications manager 1020, or a combination thereof) may support techniques for more efficient utilization of communication resources.

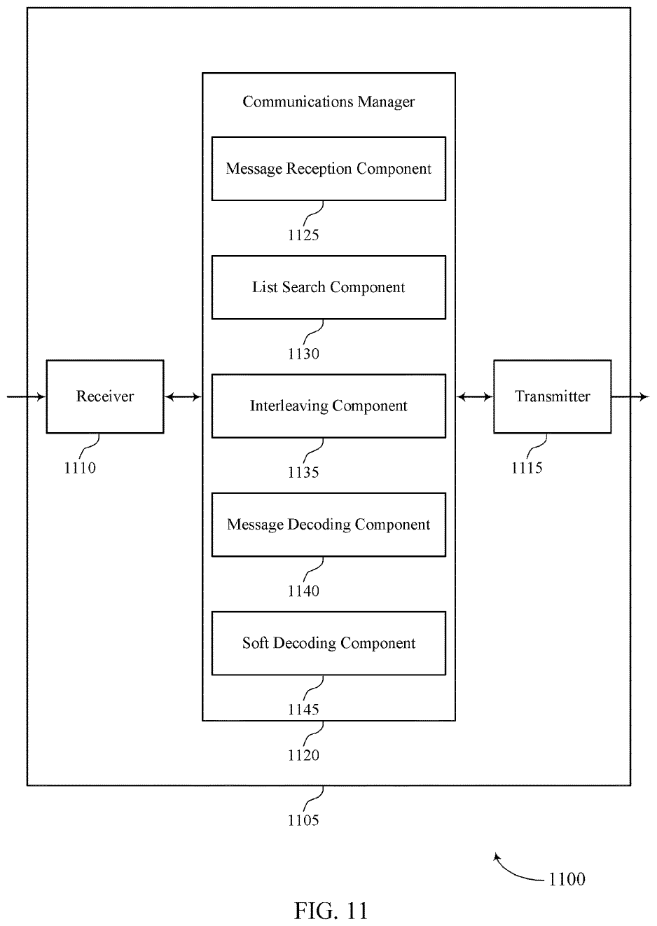

FIG. 11 shows a block diagram 1100 of a device 1105 that supports techniques for iterative decoding using turbo spinal codes in accordance with one or more aspects of the present disclosure. The device 1105 may be an example of aspects of a device 1005, a UE 115, or a network entity 105 as described herein. The device 1105 may include a receiver 1110, a transmitter 1115, and a communications manager 1120. The device 1105 may also include a processor. Each of these components may be in communication with one another (e.g., via one or more buses).

The receiver 1110 may provide a means for receiving information such as packets, user data, control information, or any combination thereof associated with various information channels (e.g., control channels, data channels, information channels related to techniques for iterative decoding using turbo spinal codes). Information may be passed on to other components of the device 1105. The receiver 1110 may utilize a single antenna or a set of multiple antennas.

The transmitter 1115 may provide a means for transmitting signals generated by other components of the device 1105. For example, the transmitter 1115 may transmit information such as packets, user data, control information, or any combination thereof associated with various information channels (e.g., control channels, data channels, information channels related to techniques for iterative decoding using turbo spinal codes). In some examples, the transmitter 1115 may be co-located with a receiver 1110 in a transceiver module. The transmitter 1115 may utilize a single antenna or a set of multiple antennas.

The device 1105, or various components thereof, may be an example of means for performing various aspects of techniques for iterative decoding using turbo spinal codes as described herein. For example, the communications manager 1120 may include a message reception component 1125, a list search component 1130, an interleaving component 1135, a message decoding component 1140, a soft decoding component 1145, or any combination thereof. The communications manager 1120 may be an example of aspects of a communications manager 1020 as described herein. In some examples, the communications manager 1120, or various components thereof, may be configured to perform various operations (e.g., receiving, obtaining, monitoring, outputting, transmitting) using or otherwise in cooperation with the receiver 1110, the transmitter 1115, or both. For example, the communications manager 1120 may receive information from the receiver 1110, send information to the transmitter 1115, or be integrated in combination with the receiver 1110, the transmitter 1115, or both to obtain information, output information, or perform various other operations as described herein.

The communications manager 1120 may support wireless communication at a wireless device in accordance with examples as disclosed herein. The message reception component 1125 may be configured as or otherwise support a means for receiving a message including a set of multiple bits partitioned into a set of multiple submessages. The list search component 1130 may be configured as or otherwise support a means for performing a first list search operation associated with a first spinal code tree of an iterative list decoding process to generate a first set of multiple submessage candidates. The interleaving component 1135 may be configured as or otherwise support a means for interleaving the first set of multiple submessage candidates to generate a set of interleaved submessage candidates. The list search component 1130 may be configured as or otherwise support a means for performing a second list search operation associated with a second spinal code tree of the iterative list decoding process using the set of interleaved submessage candidates to generate a second set of multiple submessage candidates. The message decoding component 1140 may be configured as or otherwise support a means for attempting to decode the message based on the first set of multiple submessage candidates and the second set of multiple submessage candidates.

Additionally, or alternatively, the communications manager 1120 may support wireless communication at a wireless device in accordance with examples as disclosed herein. The message reception component 1125 may be configured as or otherwise support a means for receiving a message including of a first set of multiple bits partitioned into a set of multiple submessages. The soft decoding component 1145 may be configured as or otherwise support a means for performing a first soft decoding operation associated with a first spinal code of an iterative soft decoding process to generate a first set of soft information. The interleaving component 1135 may be configured as or otherwise support a means for interleaving the first set of soft information using an interleaver to generate a set of interleaved soft information. The soft decoding component 1145 may be configured as or otherwise support a means for performing a second soft decoding operation associated with a second spinal code of the iterative soft decoding process using the set of interleaved soft information to generate a second set of soft information. The message decoding component 1140 may be configured as or otherwise support a means for attempting to decode the message based on the first set of soft information and the second set of soft information.

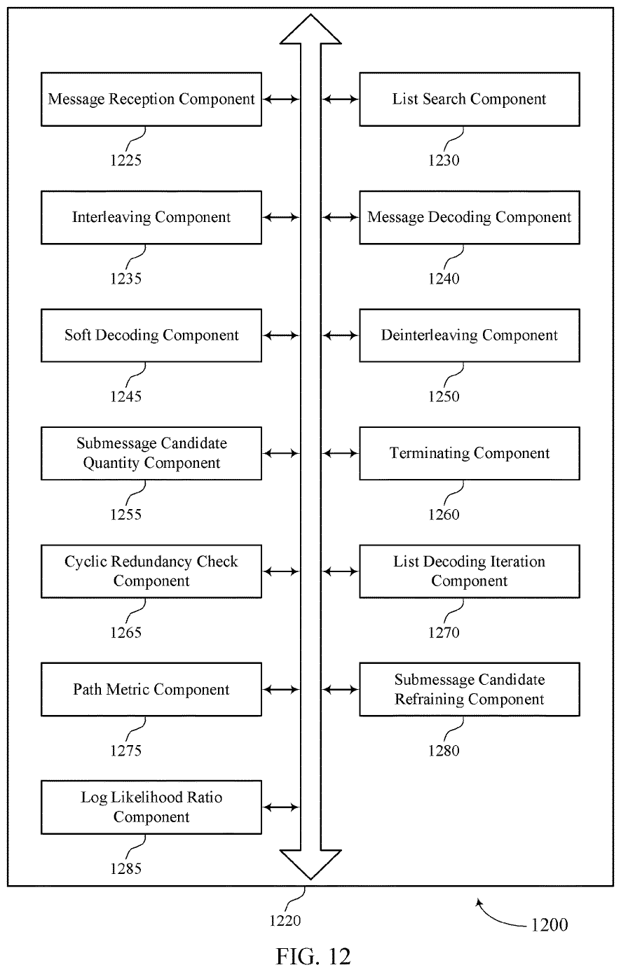

FIG. 12 shows a block diagram 1200 of a communications manager 1220 that supports techniques for iterative decoding using turbo spinal codes in accordance with one or more aspects of the present disclosure. The communications manager 1220 may be an example of aspects of a communications manager 1020, a communications manager 1120, or both, as described herein. The communications manager 1220, or various components thereof, may be an example of means for performing various aspects of techniques for iterative decoding using turbo spinal codes as described herein. For example, the communications manager 1220 may include a message reception component 1225, a list search component 1230, an interleaving component 1235, a message decoding component 1240, a soft decoding component 1245, a deinterleaving component 1250, a submessage candidate quantity component 1255, a terminating component 1260, a CRC component 1265, a list decoding iteration component 1270, a path metric component 1275, a submessage candidate refraining component 1280, a LLR component 1285, or any combination thereof. Each of these components may communicate, directly or indirectly, with one another (e.g., via one or more buses) which may include communications within a protocol layer of a protocol stack, communications associated with a logical channel of a protocol stack (e.g., between protocol layers of a protocol stack, within a device, component, or virtualized component associated with a network entity 105, between devices, components, or virtualized components associated with a network entity 105), or any combination thereof.

The communications manager 1220 may support wireless communication at a wireless device in accordance with examples as disclosed herein. The message reception component 1225 may be configured as or otherwise support a means for receiving a message including a set of multiple bits partitioned into a set of multiple submessages. The list search component 1230 may be configured as or otherwise support a means for performing a first list search operation associated with a first spinal code tree of an iterative list decoding process to generate a first set of multiple submessage candidates. The interleaving component 1235 may be configured as or otherwise support a means for interleaving the first set of multiple submessage candidates to generate a set of interleaved submessage candidates. In some examples, the list search component 1230 may be configured as or otherwise support a means for performing a second list search operation associated with a second spinal code tree of the iterative list decoding process using the set of interleaved submessage candidates to generate a second set of multiple submessage candidates. The message decoding component 1240 may be configured as or otherwise support a means for attempting to decode the message based on the first set of multiple submessage candidates and the second set of multiple submessage candidates.

In some examples, the deinterleaving component 1250 may be configured as or otherwise support a means for deinterleaving the second set of multiple submessage candidates to generate an input for the first list search operation associated with the first spinal code tree in a next iteration of the iterative list decoding process.

In some examples, the next iteration is based on a failure of a current iteration to meet a maximum iteration threshold of the iterative list decoding process.

In some examples, the interleaving, deinterleaving, or both are based on a row-in column-out rectangular interleaver, a triangular interleaver, a pseudo-random interleaver, or a two-way spinal interleaver.

In some examples, the submessage candidate quantity component 1255 may be configured as or otherwise support a means for determining a quantity of submessage candidates remaining after the attempting to decode the message. In some examples, the terminating component 1260 may be configured as or otherwise support a means for terminating the iterative list decoding process based on determining that the quantity of submessage candidates remaining after the attempting to decode the message is equal to one.

In some examples, to support attempting to decode the message, the CRC component 1265 may be configured as or otherwise support a means for performing a CRC based on a message candidate corresponding to a first submessage candidate of the first set of multiple submessage candidates and a second submessage candidate of the second set of multiple submessage candidates. In some examples, to support attempting to decode the message, the terminating component 1260 may be configured as or otherwise support a means for terminating the iterative list decoding process based on a success of the CRC.

In some examples, the submessage candidate quantity component 1255 may be configured as or otherwise support a means for identifying that at least two submessage candidates of the second set of multiple submessage candidates are remaining based on performing the second list search operation on the second spinal code tree. In some examples, the list decoding iteration component 1270 may be configured as or otherwise support a means for performing a next iteration of the iterative list decoding process based on identifying that the at least two submessage candidates of the second set of multiple submessage candidates are remaining.

In some examples, the path metric component 1275 may be configured as or otherwise support a means for determining that one or more submessage candidates fail to satisfy a path metric based on performing the second list search operation on the second spinal code tree. In some examples, the submessage candidate refraining component 1280 may be configured as or otherwise support a means for refraining from including the one or more submessage candidates in the second set of multiple submessage candidates based on the determining.

In some examples, the first set of multiple submessage candidates, the second set of multiple submessage candidates, or both are generated based on a threshold quantity of submessage candidates.

Additionally, or alternatively, the communications manager 1220 may support wireless communication at a wireless device in accordance with examples as disclosed herein. In some examples, the message reception component 1225 may be configured as or otherwise support a means for receiving a message including of a first set of multiple bits partitioned into a set of multiple submessages. The soft decoding component 1245 may be configured as or otherwise support a means for performing a first soft decoding operation associated with a first spinal code of an iterative soft decoding process to generate a first set of soft information. In some examples, the interleaving component 1235 may be configured as or otherwise support a means for interleaving the first set of soft information using an interleaver to generate a set of interleaved soft information. In some examples, the soft decoding component 1245 may be configured as or otherwise support a means for performing a second soft decoding operation associated with a second spinal code of the iterative soft decoding process using the set of interleaved soft information to generate a second set of soft information. In some examples, the message decoding component 1240 may be configured as or otherwise support a means for attempting to decode the message based on the first set of soft information and the second set of soft information.

In some examples, the deinterleaving component 1250 may be configured as or otherwise support a means for deinterleaving the second set of soft information to generate an input for the first soft decoding operation associated with the first spinal code in a next iteration of the iterative soft decoding process.

In some examples, the next iteration is based on a failure of a current iteration to meet a maximum iteration threshold of the iterative soft decoding process.

In some examples, the interleaving, deinterleaving, or both, are based on a row-in column-out rectangular interleaver, a triangular interleaver, a pseudo-random interleaver, or a two-way spinal interleaver.

In some examples, the LLR component 1285 may be configured as or otherwise support a means for determining a first LLR based on the first set of soft information. In some examples, the LLR component 1285 may be configured as or otherwise support a means for determining a second LLR based on the second set of soft information. In some examples, the terminating component 1260 may be configured as or otherwise support a means for terminating the iterative soft decoding process based on the first LLR, the second LLR, or any combination thereof.

In some examples, the CRC component 1265 may be configured as or otherwise support a means for performing a CRC based on a message candidate corresponding to the first set of soft information and the second set of soft information. In some examples, the terminating component 1260 may be configured as or otherwise support a means for terminating the iterative soft decoding process based on a success of the CRC.

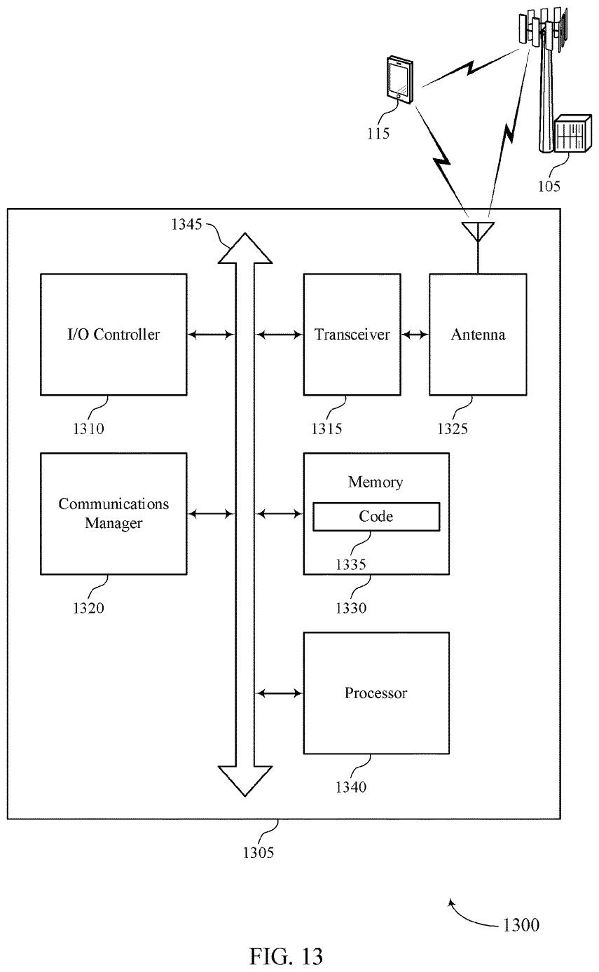

FIG. 13 shows a diagram of a system 1300 including a device 1305 that supports techniques for iterative decoding using turbo spinal codes in accordance with one or more aspects of the present disclosure. The device 1305 may be an example of or include the components of a device 1005, a device 1105, or a UE 115 as described herein. The device 1305 may communicate (e.g., wirelessly) with one or more network entities 105, one or more UEs 115, or any combination thereof. The device 1305 may include components for bi-directional voice and data communications including components for transmitting and receiving communications, such as a communications manager 1320, an input/output (I/O) controller 1310, a transceiver 1315, an antenna 1325, a memory 1330, code 1335, and a processor 1340. These components may be in electronic communication or otherwise coupled (e.g., operatively, communicatively, functionally, electronically, electrically) via one or more buses (e.g., a bus 1345).

The I/O controller 1310 may manage input and output signals for the device 1305. The I/O controller 1310 may also manage peripherals not integrated into the device 1305. In some cases, the I/O controller 1310 may represent a physical connection or port to an external peripheral. In some cases, the I/O controller 1310 may utilize an operating system such as iOS®, ANDROID®, MS-DOS®, MS-WINDOWS®, OS/2®, UNIX®, LINUX®, or another known operating system. Additionally, or alternatively, the I/O controller 1310 may represent or interact with a modem, a keyboard, a mouse, a touchscreen, or a similar device. In some cases, the I/O controller 1310 may be implemented as part of a processor, such as the processor 1340. In some cases, a user may interact with the device 1305 via the I/O controller 1310 or via hardware components controlled by the I/O controller 1310.

In some cases, the device 1305 may include a single antenna 1325. However, in some other cases, the device 1305 may have more than one antenna 1325, which may be capable of concurrently transmitting or receiving multiple wireless transmissions. The transceiver 1315 may communicate bi-directionally, via the one or more antennas 1325, wired, or wireless links as described herein. For example, the transceiver 1315 may represent a wireless transceiver and may communicate bi-directionally with another wireless transceiver. The transceiver 1315 may also include a modem to modulate the packets, to provide the modulated packets to one or more antennas 1325 for transmission, and to demodulate packets received from the one or more antennas 1325. The transceiver 1315, or the transceiver 1315 and one or more antennas 1325, may be an example of a transmitter 1015, a transmitter 1115, a receiver 1010, a receiver 1110, or any combination thereof or component thereof, as described herein.

The memory 1330 may include random access memory (RAM) and read-only memory (ROM). The memory 1330 may store computer-readable, computer-executable code 1335 including instructions that, when executed by the processor 1340, cause the device 1305 to perform various functions described herein. The code 1335 may be stored in a non-transitory computer-readable medium such as system memory or another type of memory. In some cases, the code 1335 may not be directly executable by the processor 1340 but may cause a computer (e.g., when compiled and executed) to perform functions described herein. In some cases, the memory 1330 may contain, among other things, a basic I/O system (BIOS) which may control basic hardware or software operation such as the interaction with peripheral components or devices.

The processor 1340 may include an intelligent hardware device (e.g., a general-purpose processor, a DSP, a CPU, a microcontroller, an ASIC, an FPGA, a programmable logic device, a discrete gate or transistor logic component, a discrete hardware component, or any combination thereof). In some cases, the processor 1340 may be configured to operate a memory array using a memory controller. In some other cases, a memory controller may be integrated into the processor 1340. The processor 1340 may be configured to execute computer-readable instructions stored in a memory (e.g., the memory 1330) to cause the device 1305 to perform various functions (e.g., functions or tasks supporting techniques for iterative decoding using turbo spinal codes). For example, the device 1305 or a component of the device 1305 may include a processor 1340 and memory 1330 coupled with or to the processor 1340, the processor 1340 and memory 1330 configured to perform various functions described herein.

The communications manager 1320 may support wireless communication at a wireless device in accordance with examples as disclosed herein. For example, the communications manager 1320 may be configured as or otherwise support a means for receiving a message including a set of multiple bits partitioned into a set of multiple submessages. The communications manager 1320 may be configured as or otherwise support a means for performing a first list search operation associated with a first spinal code tree of an iterative list decoding process to generate a first set of multiple submessage candidates. The communications manager 1320 may be configured as or otherwise support a means for interleaving the first set of multiple submessage candidates to generate a set of interleaved submessage candidates. The communications manager 1320 may be configured as or otherwise support a means for performing a second list search operation associated with a second spinal code tree of the iterative list decoding process using the set of interleaved submessage candidates to generate a second set of multiple submessage candidates. The communications manager 1320 may be configured as or otherwise support a means for attempting to decode the message based on the first set of multiple submessage candidates and the second set of multiple submessage candidates.

Additionally, or alternatively, the communications manager 1320 may support wireless communication at a wireless device in accordance with examples as disclosed herein. For example, the communications manager 1320 may be configured as or otherwise support a means for receiving a message including of a first set of multiple bits partitioned into a set of multiple submessages. The communications manager 1320 may be configured as or otherwise support a means for performing a first soft decoding operation associated with a first spinal code of an iterative soft decoding process to generate a first set of soft information. The communications manager 1320 may be configured as or otherwise support a means for interleaving the first set of soft information using an interleaver to generate a set of interleaved soft information. The communications manager 1320 may be configured as or otherwise support a means for performing a second soft decoding operation associated with a second spinal code of the iterative soft decoding process using the set of interleaved soft information to generate a second set of soft information. The communications manager 1320 may be configured as or otherwise support a means for attempting to decode the message based on the first set of soft information and the second set of soft information.

By including or configuring the communications manager 1320 in accordance with examples as described herein, the device 1305 may support techniques for improved communication reliability, improved user experience related to reduced processing, more efficient utilization of communication resources, and improved coordination between devices.

In some examples, the communications manager 1320 may be configured to perform various operations (e.g., receiving, monitoring, transmitting) using or otherwise in cooperation with the transceiver 1315, the one or more antennas 1325, or any combination thereof. Although the communications manager 1320 is illustrated as a separate component, in some examples, one or more functions described with reference to the communications manager 1320 may be supported by or performed by the processor 1340, the memory 1330, the code 1335, or any combination thereof. For example, the code 1335 may include instructions executable by the processor 1340 to cause the device 1305 to perform various aspects of techniques for iterative decoding using turbo spinal codes as described herein, or the processor 1340 and the memory 1330 may be otherwise configured to perform or support such operations.

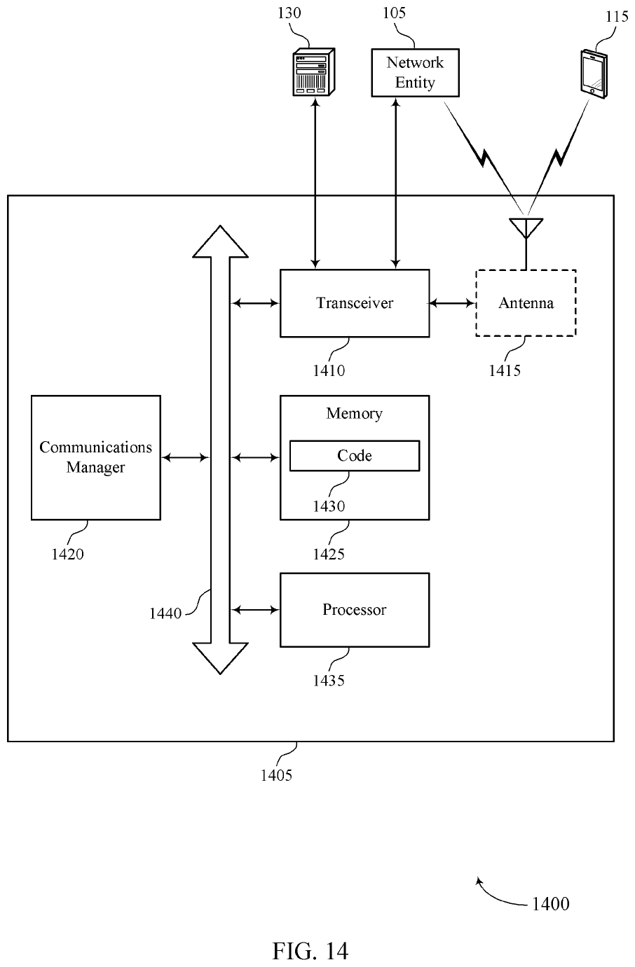

FIG. 14 shows a diagram of a system 1400 including a device 1405 that supports techniques for iterative decoding using turbo spinal codes in accordance with one or more aspects of the present disclosure. The device 1405 may be an example of or include the components of a device 1005, a device 1105, or a network entity 105 as described herein. The device 1405 may communicate with one or more network entities 105, one or more UEs 115, or any combination thereof, which may include communications over one or more wired interfaces, over one or more wireless interfaces, or any combination thereof. The device 1405 may include components that support outputting and obtaining communications, such as a communications manager 1420, a transceiver 1410, an antenna 1415, a memory 1425, code 1430, and a processor 1435. These components may be in electronic communication or otherwise coupled (e.g., operatively, communicatively, functionally, electronically, electrically) via one or more buses (e.g., a bus 1440).

The transceiver 1410 may support bi-directional communications via wired links, wireless links, or both as described herein. In some examples, the transceiver 1410 may include a wired transceiver and may communicate bi-directionally with another wired transceiver. Additionally, or alternatively, in some examples, the transceiver 1410 may include a wireless transceiver and may communicate bi-directionally with another wireless transceiver. In some examples, the device 1405 may include one or more antennas 1415, which may be capable of transmitting or receiving wireless transmissions (e.g., concurrently). The transceiver 1410 may also include a modem to modulate signals, to provide the modulated signals for transmission (e.g., by one or more antennas 1415, by a wired transmitter), to receive modulated signals (e.g., from one or more antennas 1415, from a wired receiver), and to demodulate signals. In some implementations, the transceiver 1410 may include one or more interfaces, such as one or more interfaces coupled with the one or more antennas 1415 that are configured to support various receiving or obtaining operations, or one or more interfaces coupled with the one or more antennas 1415 that are configured to support various transmitting or outputting operations, or a combination thereof. In some implementations, the transceiver 1410 may include or be configured for coupling with one or more processors or memory components that are operable to perform or support operations based on received or obtained information or signals, or to generate information or other signals for transmission or other outputting, or any combination thereof. In some implementations, the transceiver 1410, or the transceiver 1410 and the one or more antennas 1415, or the transceiver 1410 and the one or more antennas 1415 and one or more processors or memory components (for example, the processor 1435, or the memory 1425, or both), may be included in a chip or chip assembly that is installed in the device 1405. In some examples, the transceiver may be operable to support communications via one or more communications links (e.g., a communication link 125, a backhaul communication link 120, a midhaul communication link 162, a fronthaul communication link 168).

The memory 1425 may include RAM and ROM. The memory 1425 may store computer-readable, computer-executable code 1430 including instructions that, when executed by the processor 1435, cause the device 1405 to perform various functions described herein. The code 1430 may be stored in a non-transitory computer-readable medium such as system memory or another type of memory. In some cases, the code 1430 may not be directly executable by the processor 1435 but may cause a computer (e.g., when compiled and executed) to perform functions described herein. In some cases, the memory 1425 may contain, among other things, a BIOS which may control basic hardware or software operation such as the interaction with peripheral components or devices.

The processor 1435 may include an intelligent hardware device (e.g., a general-purpose processor, a DSP, an ASIC, a CPU, an FPGA, a microcontroller, a programmable logic device, discrete gate or transistor logic, a discrete hardware component, or any combination thereof). In some cases, the processor 1435 may be configured to operate a memory array using a memory controller. In some other cases, a memory controller may be integrated into the processor 1435. The processor 1435 may be configured to execute computer-readable instructions stored in a memory (e.g., the memory 1425) to cause the device 1405 to perform various functions (e.g., functions or tasks supporting techniques for iterative decoding using turbo spinal codes). For example, the device 1405 or a component of the device 1405 may include a processor 1435 and memory 1425 coupled with the processor 1435, the processor 1435 and memory 1425 configured to perform various functions described herein. The processor 1435 may be an example of a cloud-computing platform (e.g., one or more physical nodes and supporting software such as operating systems, virtual machines, or container instances) that may host the functions (e.g., by executing code 1430) to perform the functions of the device 1405. The processor 1435 may be any one or more suitable processors capable of executing scripts or instructions of one or more software programs stored in the device 1405 (such as within the memory 1425). In some implementations, the processor 1435 may be a component of a processing system. A processing system may generally refer to a system or series of machines or components that receives inputs and processes the inputs to produce a set of outputs (which may be passed to other systems or components of, for example, the device 1405). For example, a processing system of the device 1405 may refer to a system including the various other components or subcomponents of the device 1405, such as the processor 1435, or the transceiver 1410, or the communications manager 1420, or other components or combinations of components of the device 1405. The processing system of the device 1405 may interface with other components of the device 1405, and may process information received from other components (such as inputs or signals) or output information to other components. For example, a chip or modem of the device 1405 may include a processing system and one or more interfaces to output information, or to obtain information, or both. The one or more interfaces may be implemented as or otherwise include a first interface configured to output information and a second interface configured to obtain information, or a same interface configured to output information and to obtain information, among other implementations. In some implementations, the one or more interfaces may refer to an interface between the processing system of the chip or modem and a transmitter, such that the device 1405 may transmit information output from the chip or modem. Additionally, or alternatively, in some implementations, the one or more interfaces may refer to an interface between the processing system of the chip or modem and a receiver, such that the device 1405 may obtain information or signal inputs, and the information may be passed to the processing system. A person having ordinary skill in the art will readily recognize that a first interface also may obtain information or signal inputs, and a second interface also may output information or signal outputs.

In some examples, a bus 1440 may support communications of (e.g., within) a protocol layer of a protocol stack. In some examples, a bus 1440 may support communications associated with a logical channel of a protocol stack (e.g., between protocol layers of a protocol stack), which may include communications performed within a component of the device 1405, or between different components of the device 1405 that may be co-located or located in different locations (e.g., where the device 1405 may refer to a system in which one or more of the communications manager 1420, the transceiver 1410, the memory 1425, the code 1430, and the processor 1435 may be located in one of the different components or divided between different components).

In some examples, the communications manager 1420 may manage aspects of communications with a core network 130 (e.g., via one or more wired or wireless backhaul links). For example, the communications manager 1420 may manage the transfer of data communications for client devices, such as one or more UEs 115. In some examples, the communications manager 1420 may manage communications with other network entities 105, and may include a controller or scheduler for controlling communications with UEs 115 in cooperation with other network entities 105. In some examples, the communications manager 1420 may support an X2 interface within an LTE/LTE-A wireless communications network technology to provide communication between network entities 105.

The communications manager 1420 may support wireless communication at a wireless device in accordance with examples as disclosed herein. For example, the communications manager 1420 may be configured as or otherwise support a means for receiving a message including a set of multiple bits partitioned into a set of multiple submessages. The communications manager 1420 may be configured as or otherwise support a means for performing a first list search operation associated with a first spinal code tree of an iterative list decoding process to generate a first set of multiple submessage candidates. The communications manager 1420 may be configured as or otherwise support a means for interleaving the first set of multiple submessage candidates to generate a set of interleaved submessage candidates. The communications manager 1420 may be configured as or otherwise support a means for performing a second list search operation associated with a second spinal code tree of the iterative list decoding process using the set of interleaved submessage candidates to generate a second set of multiple submessage candidates. The communications manager 1420 may be configured as or otherwise support a means for attempting to decode the message based on the first set of multiple submessage candidates and the second set of multiple submessage candidates.

Additionally, or alternatively, the communications manager 1420 may support wireless communication at a wireless device in accordance with examples as disclosed herein. For example, the communications manager 1420 may be configured as or otherwise support a means for receiving a message including of a first set of multiple bits partitioned into a set of multiple submessages. The communications manager 1420 may be configured as or otherwise support a means for performing a first soft decoding operation associated with a first spinal code of an iterative soft decoding process to generate a first set of soft information. The communications manager 1420 may be configured as or otherwise support a means for interleaving the first set of soft information using an interleaver to generate a set of interleaved soft information. The communications manager 1420 may be configured as or otherwise support a means for performing a second soft decoding operation associated with a second spinal code of the iterative soft decoding process using the set of interleaved soft information to generate a second set of soft information. The communications manager 1420 may be configured as or otherwise support a means for attempting to decode the message based on the first set of soft information and the second set of soft information.

By including or configuring the communications manager 1420 in accordance with examples as described herein, the device 1405 may support techniques for improved communication reliability, improved user experience related to reduced processing, more efficient utilization of communication resources, and improved coordination between devices.

In some examples, the communications manager 1420 may be configured to perform various operations (e.g., receiving, obtaining, monitoring, outputting, transmitting) using or otherwise in cooperation with the transceiver 1410, the one or more antennas 1415 (e.g., where applicable), or any combination thereof. Although the communications manager 1420 is illustrated as a separate component, in some examples, one or more functions described with reference to the communications manager 1420 may be supported by or performed by the transceiver 1410, the processor 1435, the memory 1425, the code 1430, or any combination thereof. For example, the code 1430 may include instructions executable by the processor 1435 to cause the device 1405 to perform various aspects of techniques for iterative decoding using turbo spinal codes as described herein, or the processor 1435 and the memory 1425 may be otherwise configured to perform or support such operations.

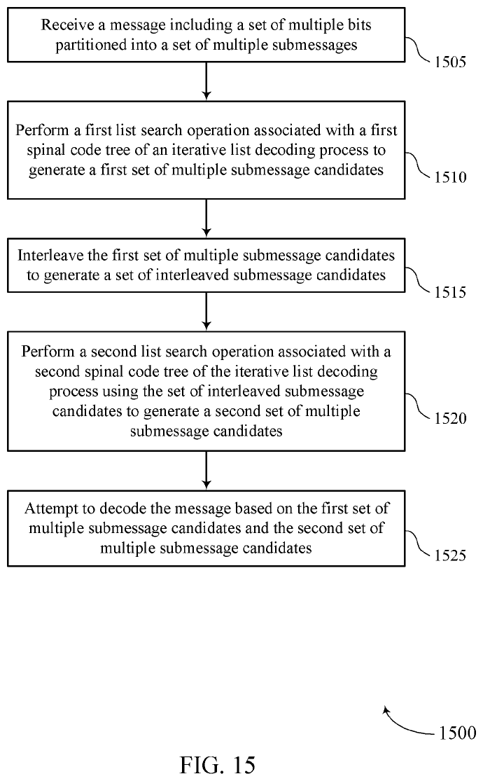

FIG. 15 shows a flowchart illustrating a method 1500 that supports techniques for iterative decoding using turbo spinal codes in accordance with one or more aspects of the present disclosure. The operations of the method 1500 may be implemented by a UE or a network entity or its components as described herein. For example, the operations of the method 1500 may be performed by a UE 115 or a network entity as described with reference to FIGS. 1 through 14. In some examples, a UE or a network entity may execute a set of instructions to control the functional elements of the UE or the network entity to perform the described functions. Additionally, or alternatively, the UE or the network entity may perform aspects of the described functions using special-purpose hardware.

At 1505, the method may include receiving a message including a set of multiple bits partitioned into a set of multiple submessages. The operations of 1505 may be performed in accordance with examples as disclosed herein. In some examples, aspects of the operations of 1505 may be performed by a message reception component 1225 as described with reference to FIG. 12.

At 1510, the method may include performing a first list search operation associated with a first spinal code tree of an iterative list decoding process to generate a first set of multiple submessage candidates. The operations of 1510 may be performed in accordance with examples as disclosed herein. In some examples, aspects of the operations of 1510 may be performed by a list search component 1230 as described with reference to FIG. 12.

At 1515, the method may include interleaving the first set of multiple submessage candidates to generate a set of interleaved submessage candidates. The operations of 1515 may be performed in accordance with examples as disclosed herein. In some examples, aspects of the operations of 1515 may be performed by an interleaving component 1235 as described with reference to FIG. 12.

At 1520, the method may include performing a second list search operation associated with a second spinal code tree of the iterative list decoding process using the set of interleaved submessage candidates to generate a second set of multiple submessage candidates. The operations of 1520 may be performed in accordance with examples as disclosed herein. In some examples, aspects of the operations of 1520 may be performed by a list search component 1230 as described with reference to FIG. 12.

At 1525, the method may include attempting to decode the message based on the first set of multiple submessage candidates and the second set of multiple submessage candidates. The operations of 1525 may be performed in accordance with examples as disclosed herein. In some examples, aspects of the operations of 1525 may be performed by a message decoding component 1240 as described with reference to FIG. 12.

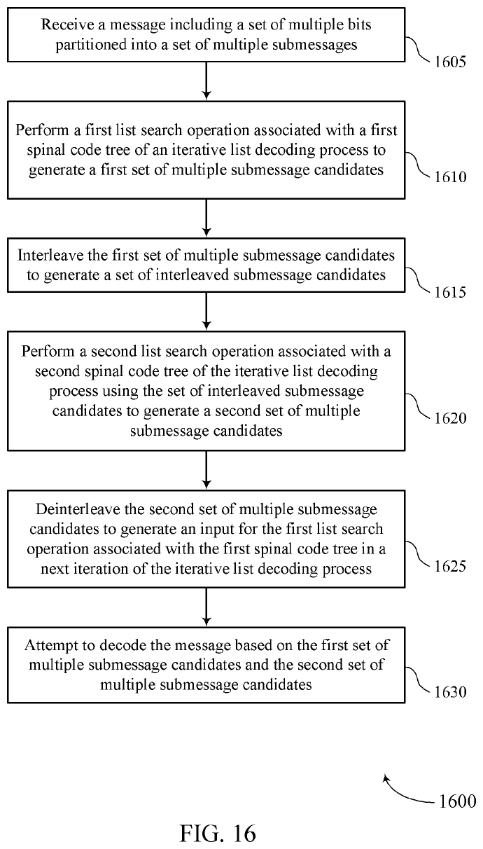

FIG. 16 shows a flowchart illustrating a method 1600 that supports techniques for iterative decoding using turbo spinal codes in accordance with one or more aspects of the present disclosure. The operations of the method 1600 may be implemented by a UE or a network entity or its components as described herein. For example, the operations of the method 1600 may be performed by a UE 115 or a network entity as described with reference to FIGS. 1 through 14. In some examples, a UE or a network entity may execute a set of instructions to control the functional elements of the UE or the network entity to perform the described functions. Additionally, or alternatively, the UE or the network entity may perform aspects of the described functions using special-purpose hardware.

At 1605, the method may include receiving a message including a set of multiple bits partitioned into a set of multiple submessages. The operations of 1605 may be performed in accordance with examples as disclosed herein. In some examples, aspects of the operations of 1605 may be performed by a message reception component 1225 as described with reference to FIG. 12.

At 1610, the method may include performing a first list search operation associated with a first spinal code tree of an iterative list decoding process to generate a first set of multiple submessage candidates. The operations of 1610 may be performed in accordance with examples as disclosed herein. In some examples, aspects of the operations of 1610 may be performed by a list search component 1230 as described with reference to FIG. 12.

At 1615, the method may include interleaving the first set of multiple submessage candidates to generate a set of interleaved submessage candidates. The operations of 1615 may be performed in accordance with examples as disclosed herein. In some examples, aspects of the operations of 1615 may be performed by an interleaving component 1235 as described with reference to FIG. 12.

At 1620, the method may include performing a second list search operation associated with a second spinal code tree of the iterative list decoding process using the set of interleaved submessage candidates to generate a second set of multiple submessage candidates. The operations of 1620 may be performed in accordance with examples as disclosed herein. In some examples, aspects of the operations of 1620 may be performed by a list search component 1230 as described with reference to FIG. 12.

At 1625, the method may include deinterleaving the second set of multiple submessage candidates to generate an input for the first list search operation associated with the first spinal code tree in a next iteration of the iterative list decoding process. The operations of 1625 may be performed in accordance with examples as disclosed herein. In some examples, aspects of the operations of 1625 may be performed by a deinterleaving component 1250 as described with reference to FIG. 12.

At 1630, the method may include attempting to decode the message based on the first set of multiple submessage candidates and the second set of multiple submessage candidates. The operations of 1630 may be performed in accordance with examples as disclosed herein. In some examples, aspects of the operations of 1630 may be performed by a message decoding component 1240 as described with reference to FIG. 12.

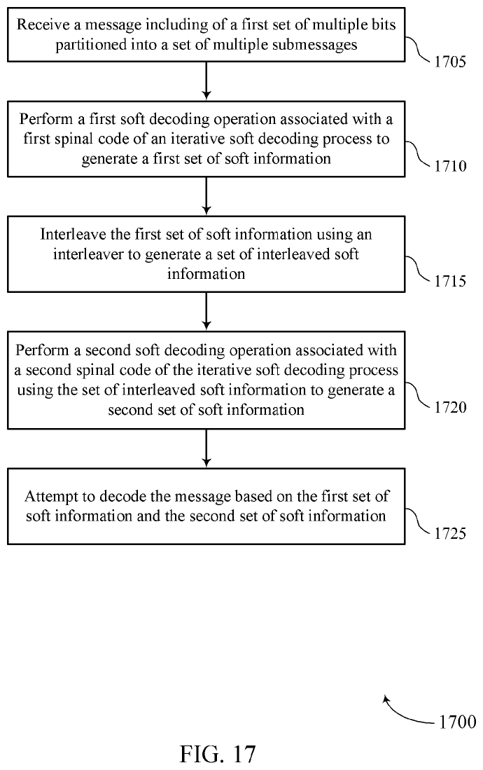

FIG. 17 shows a flowchart illustrating a method 1700 that supports techniques for iterative decoding using turbo spinal codes in accordance with one or more aspects of the present disclosure. The operations of the method 1700 may be implemented by a UE or a network entity or its components as described herein. For example, the operations of the method 1700 may be performed by a UE 115 or a network entity as described with reference to FIGS. 1 through 14. In some examples, a UE or a network entity may execute a set of instructions to control the functional elements of the UE or the network entity to perform the described functions. Additionally, or alternatively, the UE or the network entity may perform aspects of the described functions using special-purpose hardware.

At 1705, the method may include receiving a message including of a first set of multiple bits partitioned into a set of multiple submessages. The operations of 1705 may be performed in accordance with examples as disclosed herein. In some examples, aspects of the operations of 1705 may be performed by a message reception component 1225 as described with reference to FIG. 12.

At 1710, the method may include performing a first soft decoding operation associated with a first spinal code of an iterative soft decoding process to generate a first set of soft information. The operations of 1710 may be performed in accordance with examples as disclosed herein. In some examples, aspects of the operations of 1710 may be performed by a soft decoding component 1245 as described with reference to FIG. 12.

At 1715, the method may include interleaving the first set of soft information using an interleaver to generate a set of interleaved soft information. The operations of 1715 may be performed in accordance with examples as disclosed herein. In some examples, aspects of the operations of 1715 may be performed by an interleaving component 1235 as described with reference to FIG. 12.

At 1720, the method may include performing a second soft decoding operation associated with a second spinal code of the iterative soft decoding process using the set of interleaved soft information to generate a second set of soft information. The operations of 1720 may be performed in accordance with examples as disclosed herein. In some examples, aspects of the operations of 1720 may be performed by a soft decoding component 1245 as described with reference to FIG. 12.

At 1725, the method may include attempting to decode the message based on the first set of soft information and the second set of soft information. The operations of 1725 may be performed in accordance with examples as disclosed herein. In some examples, aspects of the operations of 1725 may be performed by a message decoding component 1240 as described with reference to FIG. 12.

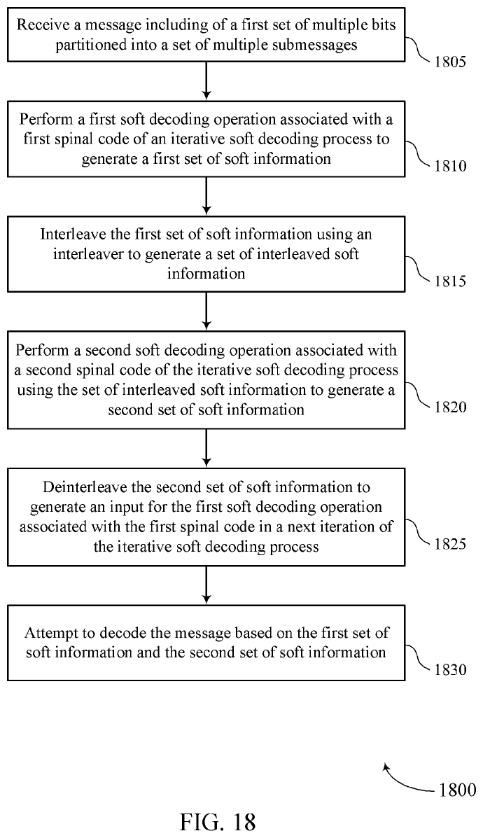

FIG. 18 shows a flowchart illustrating a method 1800 that supports techniques for iterative decoding using turbo spinal codes in accordance with one or more aspects of the present disclosure. The operations of the method 1800 may be implemented by a UE or a network entity or its components as described herein. For example, the operations of the method 1800 may be performed by a UE 115 or a network entity as described with reference to FIGS. 1 through 14. In some examples, a UE or a network entity may execute a set of instructions to control the functional elements of the UE or the network entity to perform the described functions. Additionally, or alternatively, the UE or the network entity may perform aspects of the described functions using special-purpose hardware.

At 1805, the method may include receiving a message including of a first set of multiple bits partitioned into a set of multiple submessages. The operations of 1805 may be performed in accordance with examples as disclosed herein. In some examples, aspects of the operations of 1805 may be performed by a message reception component 1225 as described with reference to FIG. 12.

At 1810, the method may include performing a first soft decoding operation associated with a first spinal code of an iterative soft decoding process to generate a first set of soft information. The operations of 1810 may be performed in accordance with examples as disclosed herein. In some examples, aspects of the operations of 1810 may be performed by a soft decoding component 1245 as described with reference to FIG. 12.

At 1815, the method may include interleaving the first set of soft information using an interleaver to generate a set of interleaved soft information. The operations of 1815 may be performed in accordance with examples as disclosed herein. In some examples, aspects of the operations of 1815 may be performed by an interleaving component 1235 as described with reference to FIG. 12.

At 1820, the method may include performing a second soft decoding operation associated with a second spinal code of the iterative soft decoding process using the set of interleaved soft information to generate a second set of soft information. The operations of 1820 may be performed in accordance with examples as disclosed herein. In some examples, aspects of the operations of 1820 may be performed by a soft decoding component 1245 as described with reference to FIG. 12.

At 1825, the method may include deinterleaving the second set of soft information to generate an input for the first soft decoding operation associated with the first spinal code in a next iteration of the iterative soft decoding process. The operations of 1825 may be performed in accordance with examples as disclosed herein. In some examples, aspects of the operations of 1825 may be performed by a deinterleaving component 1250 as described with reference to FIG. 12.

At 1830, the method may include attempting to decode the message based on the first set of soft information and the second set of soft information. The operations of 1830 may be performed in accordance with examples as disclosed herein. In some examples, aspects of the operations of 1830 may be performed by a message decoding component 1240 as described with reference to FIG. 12.

The following provides an overview of aspects of the present disclosure:

Aspect 1: A method for wireless communication at a wireless device, comprising: receiving a message comprising a plurality of bits partitioned into a plurality of submessages; performing a first list search operation associated with a first spinal code tree of an iterative list decoding process to generate a first plurality of submessage candidates; interleaving the first plurality of submessage candidates to generate a set of interleaved submessage candidates; performing a second list search operation associated with a second spinal code tree of the iterative list decoding process using the set of interleaved submessage candidates to generate a second plurality of submessage candidates; and attempting to decode the message based at least in part on the first plurality of submessage candidates and the second plurality of submessage candidates.

Aspect 2: The method of aspect 1, further comprising: deinterleaving the second plurality of submessage candidates to generate an input for the first list search operation associated with the first spinal code tree in a next iteration of the iterative list decoding process.

Aspect 3: The method of aspect 2, wherein the next iteration is based at least in part on a failure of a current iteration to meet a maximum iteration threshold of the iterative list decoding process.

Aspect 4: The method of any of aspects 2 through 3, wherein the interleaving, deinterleaving, or both are based at least in part on a row-in column-out rectangular interleaver, a triangular interleaver, a pseudo-random interleaver, or a two-way spinal interleaver.

Aspect 5: The method of any of aspects 1 through 4, further comprising: determining a quantity of submessage candidates remaining after the attempting to decode the message; and terminating the iterative list decoding process based at least in part on determining that the quantity of submessage candidates remaining after the attempting to decode the message is equal to one.

Aspect 6: The method of any of aspects 1 through 5, wherein the attempting to decode the message comprises: performing a cyclic redundancy check based at least in part on a message candidate corresponding to a first submessage candidate of the first plurality of submessage candidates and a second submessage candidate of the second plurality of submessage candidates; and terminating the iterative list decoding process based at least in part on a success of the cyclic redundancy check.

Aspect 7: The method of any of aspects 1 through 6, further comprising: identifying that at least two submessage candidates of the second plurality of submessage candidates are remaining based at least in part on performing the second list search operation on the second spinal code tree; and performing a next iteration of the iterative list decoding process based at least in part on identifying that the at least two submessage candidates of the second plurality of submessage candidates are remaining.

Aspect 8: The method of any of aspects 1 through 7, further comprising: determining that one or more submessage candidates fail to satisfy a path metric based at least in part on performing the second list search operation on the second spinal code tree; and refraining from including the one or more submessage candidates in the second plurality of submessage candidates based at least in part on the determining.

Aspect 9: The method of any of aspects 1 through 8, wherein the first plurality of submessage candidates, the second plurality of submessage candidates, or both are generated based at least in part on a threshold quantity of submessage candidates.

Aspect 10: A method for wireless communication at a wireless device, comprising: receiving a message comprising of a first plurality of bits partitioned into a plurality of submessages; performing a first soft decoding operation associated with a first spinal code of an iterative soft decoding process to generate a first set of soft information; interleaving the first set of soft information using an interleaver to generate a set of interleaved soft information; performing a second soft decoding operation associated with a second spinal code of the iterative soft decoding process using the set of interleaved soft information to generate a second set of soft information; and attempting to decode the message based at least in part on the first set of soft information and the second set of soft information.

Aspect 11: The method of aspect 10, further comprising: deinterleaving the second set of soft information to generate an input for the first soft decoding operation associated with the first spinal code in a next iteration of the iterative soft decoding process.

Aspect 12: The method of aspect 11, wherein the next iteration is based at least in part on a failure of a current iteration to meet a maximum iteration threshold of the iterative soft decoding process.

Aspect 13: The method of any of aspects 11 through 12, wherein the interleaving, deinterleaving, or both, are based at least in part on a row-in column-out rectangular interleaver, a triangular interleaver, a pseudo-random interleaver, or a two-way spinal interleaver.

Aspect 14: The method of any of aspects 10 through 13, further comprising: determining a first log likelihood ratio based at least in part on the first set of soft information; determining a second log likelihood ratio based at least in part on the second set of soft information; and terminating the iterative soft decoding process based at least in part on the first log likelihood ratio, the second log likelihood ratio, or any combination thereof.

Aspect 15: The method of any of aspects 10 through 14, further comprising: performing a cyclic redundancy check based at least in part on a message candidate corresponding to the first set of soft information and the second set of soft information; and terminating the iterative soft decoding process based at least in part on a success of the cyclic redundancy check.

Aspect 16: An apparatus for wireless communication at a wireless device, comprising a processor; memory coupled with the processor; and instructions stored in the memory and executable by the processor to cause the apparatus to perform a method of any of aspects 1 through 9.

Aspect 17: An apparatus for wireless communication at a wireless device, comprising at least one means for performing a method of any of aspects 1 through 9.

Aspect 18: A non-transitory computer-readable medium storing code for wireless communication at a wireless device, the code comprising instructions executable by a processor to perform a method of any of aspects 1 through 9.

Aspect 19: An apparatus for wireless communication at a wireless device, comprising a processor; memory coupled with the processor; and instructions stored in the memory and executable by the processor to cause the apparatus to perform a method of any of aspects 10 through 15.

Aspect 20: An apparatus for wireless communication at a wireless device, comprising at least one means for performing a method of any of aspects 10 through 15.

Aspect 21: A non-transitory computer-readable medium storing code for wireless communication at a wireless device, the code comprising instructions executable by a processor to perform a method of any of aspects 10 through 15.

It should be noted that the methods described herein describe possible implementations, and that the operations and the steps may be rearranged or otherwise modified and that other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented using hardware, software executed by a processor, firmware, or any combination thereof. If implemented using software executed by a processor, the functions may be stored as or transmitted using one or more instructions or code of a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk and Blu-ray disc. Disks may reproduce data magnetically, and discs may reproduce data optically using lasers. Combinations of the above are also included within the scope of computer-readable media.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.”

The term “determine” or “determining” encompasses a variety of actions and, therefore, “determining” can include calculating, computing, processing, deriving, investigating, looking up (such as via looking up in a table, a database or another data structure), ascertaining and the like. Also, “determining” can include receiving (e.g., receiving information), accessing (e.g., accessing data stored in memory) and the like. Also, “determining” can include resolving, obtaining, selecting, choosing, establishing, and other such similar actions.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label, or other subsequent reference label.

The description set forth herein, in connection with the appended drawings, describes example configurations and does not represent all the examples that may be implemented or that are within the scope of the claims. The term “example” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method for wireless communication at a wireless device, comprising:
receiving a message comprising a plurality of bits partitioned into a plurality of submessages;
performing a first list search operation associated with a first spinal code tree of an iterative list decoding process to generate a first plurality of submessage candidates;
interleaving the first plurality of submessage candidates to generate a set of interleaved submessage candidates;
performing a second list search operation associated with a second spinal code tree of the iterative list decoding process using the set of interleaved submessage candidates to generate a second plurality of submessage candidates; and
attempting to decode the message based at least in part on the first plurality of submessage candidates and the second plurality of submessage candidates.

2. The method of claim 1, further comprising:
deinterleaving the second plurality of submessage candidates to generate an input for the first list search operation associated with the first spinal code tree in a next iteration of the iterative list decoding process.

3. The method of claim 2, wherein the next iteration is based at least in part on a failure of a current iteration to meet a maximum iteration threshold of the iterative list decoding process.

4. The method of claim 1, further comprising:
determining a quantity of submessage candidates remaining after the attempting to decode the message; and
terminating the iterative list decoding process based at least in part on determining that the quantity of submessage candidates remaining after the attempting to decode the message is equal to one.

5. The method of claim 1, wherein the attempting to decode the message comprises:
performing a cyclic redundancy check based at least in part on a message candidate corresponding to a first submessage candidate of the first plurality of submessage candidates and a second submessage candidate of the second plurality of submessage candidates; and
terminating the iterative list decoding process based at least in part on a success of the cyclic redundancy check.

6. The method of claim 1, further comprising:
identifying that at least two submessage candidates of the second plurality of submessage candidates are remaining based at least in part on performing the second list search operation on the second spinal code tree; and
performing a next iteration of the iterative list decoding process based at least in part on identifying that the at least two submessage candidates of the second plurality of submessage candidates are remaining.

7. The method of claim 1, further comprising:
determining that one or more submessage candidates fail to satisfy a path metric based at least in part on performing the second list search operation on the second spinal code tree; and
refraining from including the one or more submessage candidates in the second plurality of submessage candidates based at least in part on the determining.

8. The method of claim 2, wherein the interleaving, deinterleaving, or both are based at least in part on a row-in column-out rectangular interleaver, a triangular interleaver, a pseudo-random interleaver, or a two-way spinal interleaver.

9. The method of claim 1, wherein the first plurality of submessage candidates, the second plurality of submessage candidates, or both are generated based at least in part on a threshold quantity of submessage candidates.

10. A method for wireless communication at a wireless device, comprising:
receiving a message comprising of a first plurality of bits partitioned into a plurality of submessages;
performing a first soft decoding operation associated with a first spinal code of an iterative soft decoding process to generate a first set of soft information;
interleaving the first set of soft information using an interleaver to generate a set of interleaved soft information;
performing a second soft decoding operation associated with a second spinal code of the iterative soft decoding process using the set of interleaved soft information to generate a second set of soft information; and
attempting to decode the message based at least in part on the first set of soft information and the second set of soft information.

11. The method of claim 10, further comprising:
deinterleaving the second set of soft information to generate an input for the first soft decoding operation associated with the first spinal code in a next iteration of the iterative soft decoding process.

12. The method of claim 11, wherein the next iteration is based at least in part on a failure of a current iteration to meet a maximum iteration threshold of the iterative soft decoding process.

13. The method of claim 10, further comprising:
determining a first log likelihood ratio based at least in part on the first set of soft information;
determining a second log likelihood ratio based at least in part on the second set of soft information; and
terminating the iterative soft decoding process based at least in part on the first log likelihood ratio, the second log likelihood ratio, or any combination thereof.

14. The method of claim 10, further comprising:
performing a cyclic redundancy check based at least in part on a message candidate corresponding to the first set of soft information and the second set of soft information; and
terminating the iterative soft decoding process based at least in part on a success of the cyclic redundancy check.

15. The method of claim 11, wherein the interleaving, deinterleaving, or both, are based at least in part on a row-in column-out rectangular interleaver, a triangular interleaver, a pseudo-random interleaver, or a two-way spinal interleaver.

16. An apparatus for wireless communication at a wireless device, comprising:
a processor;
memory coupled with the processor; and
instructions stored in the memory and executable by the processor to cause the apparatus to:
receive a message comprising a plurality of bits partitioned into a plurality of submessages;
perform a first list search operation associated with a first spinal code tree of an iterative list decoding process to generate a first plurality of submessage candidates;
interleave the first plurality of submessage candidates to generate a set of interleaved submessage candidates;
perform a second list search operation associated with a second spinal code tree of the iterative list decoding process using the set of interleaved submessage candidates to generate a second plurality of submessage candidates; and
attempt to decode the message based at least in part on the first plurality of submessage candidates and the second plurality of submessage candidates.

17. The apparatus of claim 16, wherein the instructions are further executable by the processor to cause the apparatus to:
deinterleave the second plurality of submessage candidates to generate an input for the first list search operation associated with the first spinal code tree in a next iteration of the iterative list decoding process.

18. The apparatus of claim 17, wherein the next iteration is based at least in part on a failure of a current iteration to meet a maximum iteration threshold of the iterative list decoding process.

19. The apparatus of claim 16, wherein the instructions are further executable by the processor to cause the apparatus to:
determine a quantity of submessage candidates remaining after the attempting to decode the message; and
terminate the iterative list decoding process based at least in part on determining that the quantity of submessage candidates remaining after the attempting to decode the message is equal to one.

20. The apparatus of claim 16, wherein the instructions to attempt to decode the message are executable by the processor to cause the apparatus to:
perform a cyclic redundancy check based at least in part on a message candidate corresponding to a first submessage candidate of the first plurality of submessage candidates and a second submessage candidate of the second plurality of submessage candidates; and
terminate the iterative list decoding process based at least in part on a success of the cyclic redundancy check.

21. The apparatus of claim 16, wherein the instructions are further executable by the processor to cause the apparatus to:
identify that at least two submessage candidates of the second plurality of submessage candidates are remaining based at least in part on performing the second list search operation on the second spinal code tree; and
perform a next iteration of the iterative list decoding process based at least in part on identifying that the at least two submessage candidates of the second plurality of submessage candidates are remaining.

22. The apparatus of claim 16, wherein the instructions are further executable by the processor to cause the apparatus to:
determine that one or more submessage candidates fail to satisfy a path metric based at least in part on performing the second list search operation on the second spinal code tree; and
refrain from including the one or more submessage candidates in the second plurality of submessage candidates based at least in part on the determining.

23. The apparatus of claim 17, wherein the interleaving, deinterleaving, or both are based at least in part on a row-in column-out rectangular interleaver, a triangular interleaver, a pseudo-random interleaver, or a two-way spinal interleaver.

24. The apparatus of claim 16, wherein the first plurality of submessage candidates, the second plurality of submessage candidates, or both are generated based at least in part on a threshold quantity of submessage candidates.

25. An apparatus for wireless communication at a wireless device, comprising:
a processor;
memory coupled with the processor; and
instructions stored in the memory and executable by the processor to cause the apparatus to:
receive a message comprising of a first plurality of bits partitioned into a plurality of submessages;
perform a first soft decoding operation associated with a first spinal code of an iterative soft decoding process to generate a first set of soft information;
interleave the first set of soft information using an interleaver to generate a set of interleaved soft information;
perform a second soft decoding operation associated with a second spinal code of the iterative soft decoding process using the set of interleaved soft information to generate a second set of soft information; and
attempt to decode the message based at least in part on the first set of soft information and the second set of soft information.

26. The apparatus of claim 25, wherein the instructions are further executable by the processor to cause the apparatus to:
deinterleave the second set of soft information to generate an input for the first soft decoding operation associated with the first spinal code in a next iteration of the iterative soft decoding process.

27. The apparatus of claim 26, wherein the next iteration is based at least in part on a failure of a current iteration to meet a maximum iteration threshold of the iterative soft decoding process.

28. The apparatus of claim 25, wherein the instructions are further executable by the processor to cause the apparatus to:
determine a first log likelihood ratio based at least in part on the first set of soft information;
determine a second log likelihood ratio based at least in part on the second set of soft information; and
terminate the iterative soft decoding process based at least in part on the first log likelihood ratio, the second log likelihood ratio, or any combination thereof.

29. The apparatus of claim 25, wherein the instructions are further executable by the processor to cause the apparatus to:
perform a cyclic redundancy check based at least in part on a message candidate corresponding to the first set of soft information and the second set of soft information; and
terminate the iterative soft decoding process based at least in part on a success of the cyclic redundancy check.

30. The apparatus of claim 26, wherein the interleaving, deinterleaving, or both, are based at least in part on a row-in column-out rectangular interleaver, a triangular interleaver, a pseudo-random interleaver, or a two-way spinal interleaver.
